(19) United States
(12) Patent Application Publication
(10) Pub. No.: US 2024/0321819 A1
(43) Pub. Date: Sep. 26, 2024

(54) METHOD FOR MANUFACTURING SEMICONDUCTOR DEVICE AND SEMICONDUCTOR DEVICE

(71) Applicant: Kioxia Corporation, Tokyo (JP)

(72) Inventors: Miki TOSHIMA, Nagoya Aichi (JP); Sadatoshi MURAKAMI, Yokkaichi Mie (JP); Atsushi OGA, Yokkaichi Mie (JP)

(73) Assignee: Kioxia Corporation, Tokyo (JP)

(21) Appl. No.: 18/592,860

(22) Filed: Mar. 1, 2024

(30) Foreign Application Priority Data
Mar. 20, 2023 (JP) 2023-044617

(51) Int. Cl. H01L 23/00; H10B 80/00

(52) U.S. Cl. CPC H01L 24/80; H01L 24/08; H10B 80/00; H01L 2224/08145; H01L 2224/80006; H01L 2224/80895; H01L 2224/80896

(57) ABSTRACT

According to one embodiment, a method for manufacturing a semiconductor device includes: preparing a first substrate provided with a first film; forming a second film on or above a second substrate; forming a third film on or above the second film; forming a fourth film on or above the third film; forming a stacked body by bonding a main surface of the first film and a main surface of the fourth film; performing irradiation with a laser beam from a side of the second substrate of the stacked body; and separating the second substrate in a state of including at least portion of the second film. The second film and the fourth film each includes a first material. The third film includes a second material different from the first material. The second film and the third film have different composition. The fourth film and the third film have different composition.

### CROSS-REFERENCE TO RELATED APPLICATIONS

This application is based upon and claims the benefit of Japanese Patent Application No. 2023-044617, filed on Mar. 20, 2023; the entire contents of which are incorporated herein by reference.

### FIELD

Embodiments described herein relate generally to a method for manufacturing a semiconductor device and a semiconductor device.

### BACKGROUND

In manufacturing a semiconductor device, two substrates may be bonded, and then one of the two substrates may be separated. It is desirable to appropriately perform this separation.

### BRIEF DESCRIPTION OF THE DRAWINGS

FIG. 1 is a flowchart illustrating a method for manufacturing a semiconductor device according to an embodiment;

FIGS. 2A to 2G are cross-sectional views illustrating the method for manufacturing the semiconductor device according to the embodiment;

FIGS. 3A and 3B are enlarged cross-sectional views illustrating the method for manufacturing the semiconductor device according to the embodiment;

FIGS. 4A and 4B are cross-sectional views illustrating the method for manufacturing the semiconductor device according to the embodiment;

FIG. 5 is an enlarged cross-sectional view illustrating the method for manufacturing the semiconductor device according to the embodiment;

FIGS. 6A to 6C are cross-sectional views illustrating the method for manufacturing the semiconductor device according to the embodiment;

FIGS. 7A to 7C are diagrams illustrating temperature distribution of a substrate at a time of laser beam irradiation according to the embodiment;

FIGS. 8A and 8B are cross-sectional views illustrating a flow of heat of the substrate at the time of laser beam irradiation according to the embodiment;

FIG. 9 is a diagram illustrating thermal conductivity and thermal diffusivity according to the embodiment;

FIGS. 10A to 10C are cross-sectional views illustrating the method for manufacturing the semiconductor device according to the embodiment;

FIG. 11 is a cross-sectional view illustrating generation of stress in the embodiment;

FIGS. 12A to 12F are cross-sectional views illustrating the method for manufacturing the semiconductor device according to the embodiment;

FIG. 13 is an enlarged cross-sectional view illustrating the method for manufacturing the semiconductor device according to the embodiment;

FIGS. 14A to 14C are diagrams illustrating temperature distribution of a substrate at a time of laser beam irradiation according to a first modification of the embodiment;

FIGS. 15A to 15C are diagrams illustrating temperature distribution of a substrate at a time of laser beam irradiation according to a second modification of the embodiment;

FIGS. 16A to 16C are diagrams illustrating temperature distribution of a substrate at a time of laser beam irradiation according to a fourth modification of the embodiment;

FIGS. 17A to 17C are diagrams illustrating temperature distribution of a substrate at a time of laser beam irradiation according to a fifth modification of the embodiment;

FIG. 18 is a cross-sectional view illustrating a method for manufacturing a semiconductor device according to a sixth modification of the embodiment;

FIGS. 19A to 19E are plan views illustrating the method for manufacturing the semiconductor device according to the sixth modification of the embodiment;

FIGS. 20A to 20E are cross-sectional views illustrating a method for manufacturing a semiconductor device according to a seventh modification of the embodiment;

FIGS. 21A to 21F are cross-sectional views illustrating a method for manufacturing a semiconductor device according to an eighth modification of the embodiment;

FIGS. 22A to 22E are cross-sectional views illustrating the method for manufacturing the semiconductor device according to the eighth modification of the embodiment;

FIGS. 23A to 23D are cross-sectional views illustrating the method for manufacturing the semiconductor device according to the eighth modification of the embodiment;

FIGS. 24A to 24E are cross-sectional views illustrating the method for manufacturing the semiconductor device according to the eighth modification of the embodiment; and

FIGS. 25A to 25E are cross-sectional views illustrating a method for manufacturing a semiconductor device according to a ninth modification of the embodiment.

### DETAILED DESCRIPTION

In general, according to one embodiment, there is provided a method for manufacturing a semiconductor device. The method includes preparing a first substrate provided with a first film. The method includes forming a second film on or above a second substrate. The method includes forming a third film on or above the second film. The method includes forming a fourth film on or above the third film. The method includes forming a stacked body by bonding a main surface of the first film and a main surface of the fourth film. The method includes performing irradiation with a laser beam from a side of the second substrate of the stacked body. The method includes separating the second substrate in a state of including at least portion of the second film. The second film and the fourth film each includes a first material. The third film includes a second material different from the first material. The second film and the third film have different composition. The fourth film and the third film have different composition.

Exemplary embodiments of a method for manufacturing a semiconductor device will be explained below in detail with reference to the accompanying drawings. The present invention is not limited to the following embodiments.

### Embodiment

Hereinafter, with the other substrate remaining without being peeled out of two substrates to be bonded as a reference, a direction perpendicular to a main surface of the other substrate is defined as a Z direction, and two directions orthogonal to each other in a plane perpendicular to the Z direction are defined as an X direction and a Y direction.

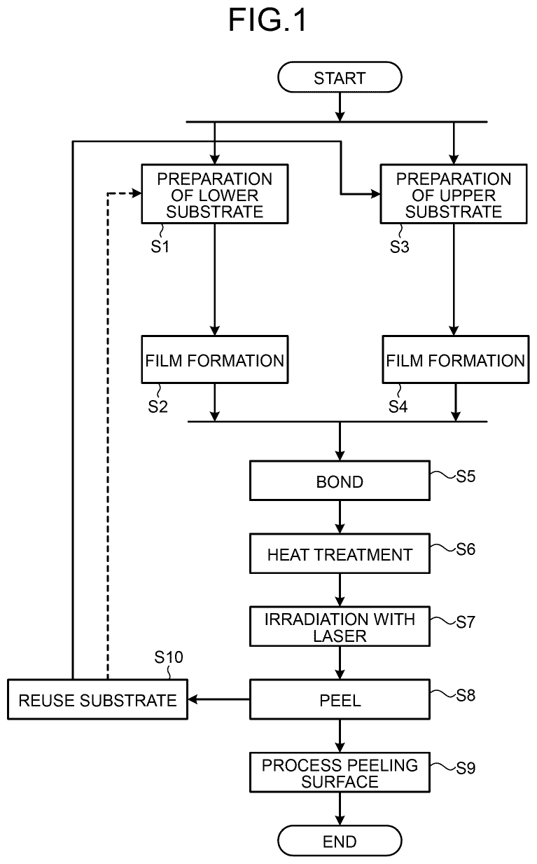

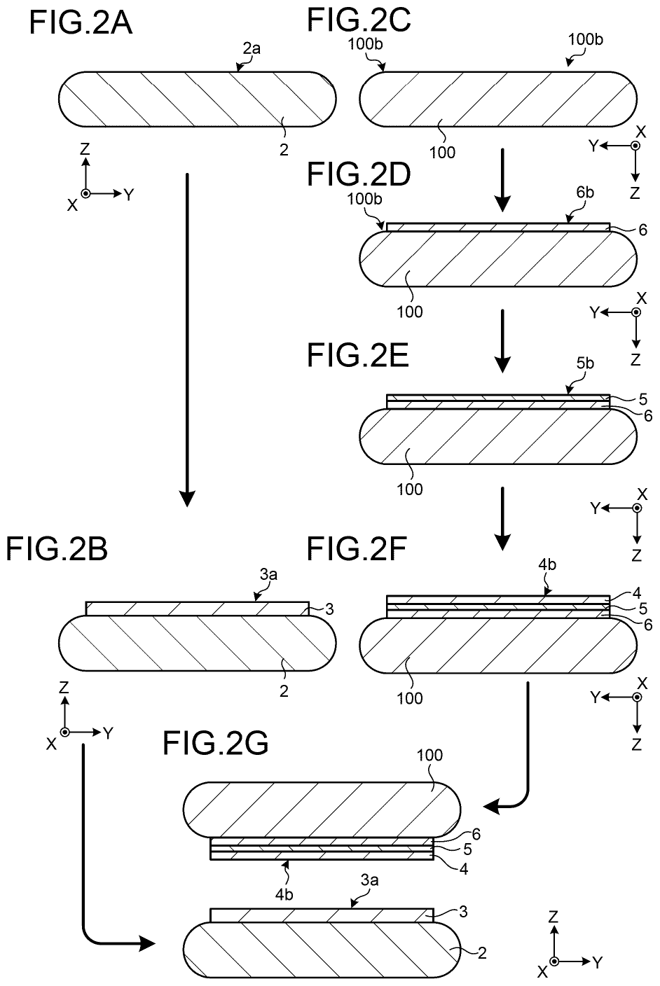

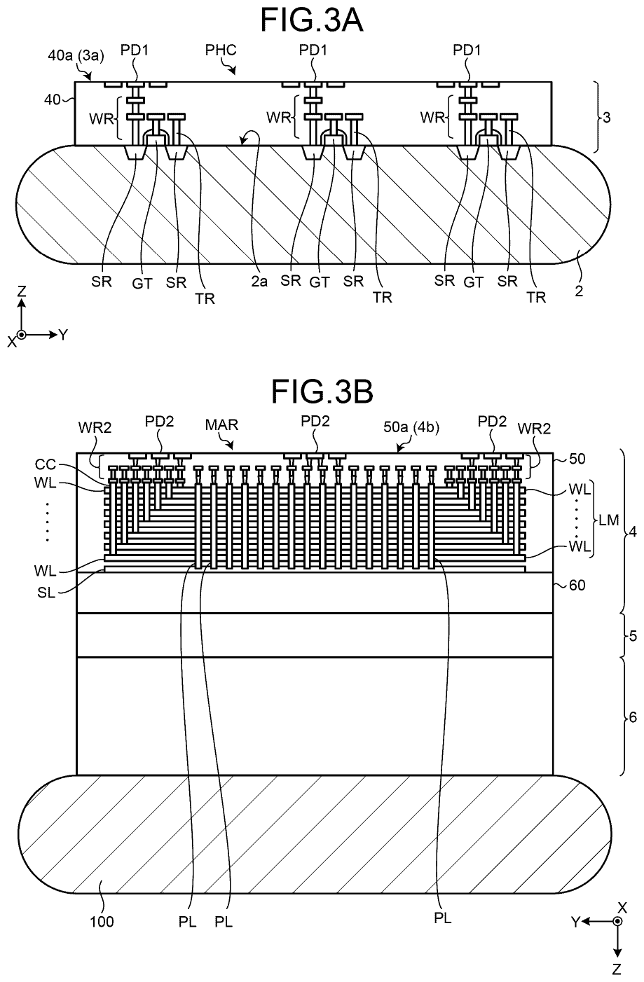

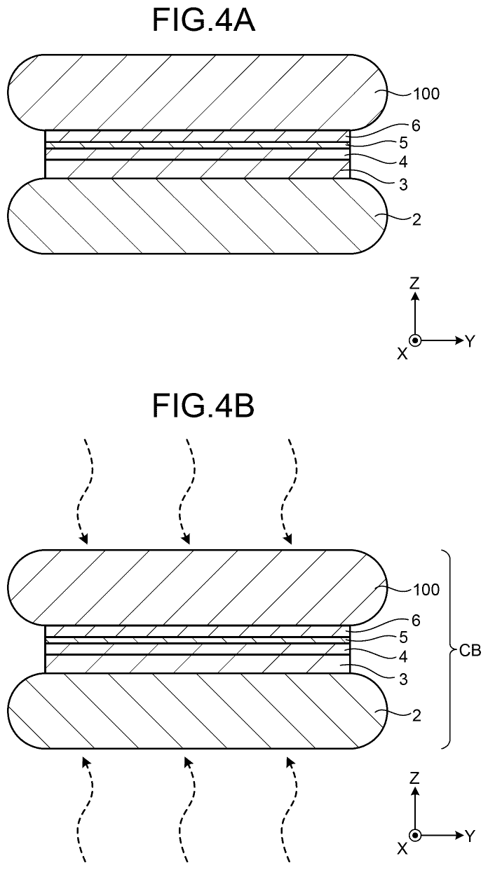

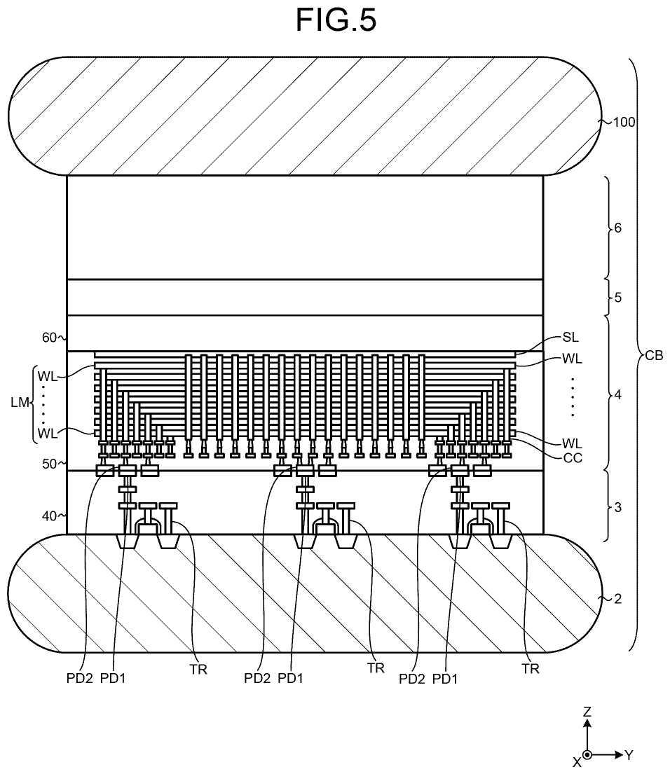

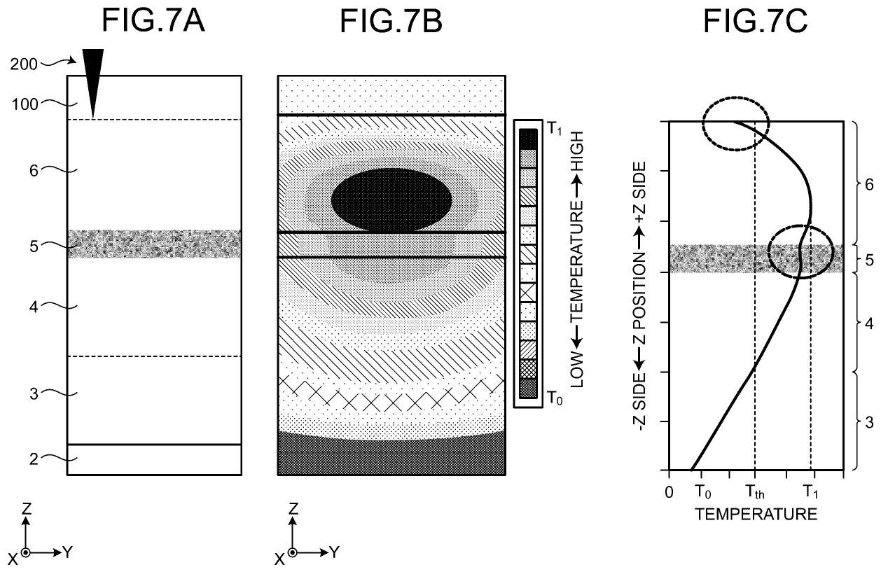

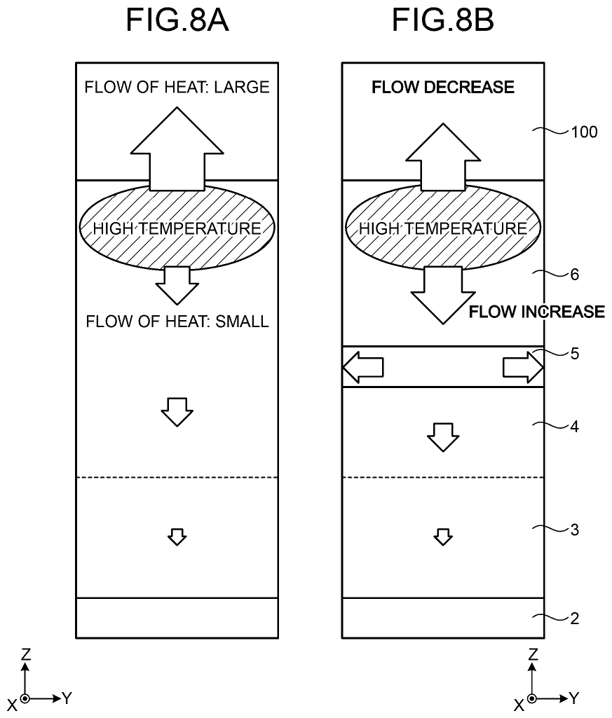

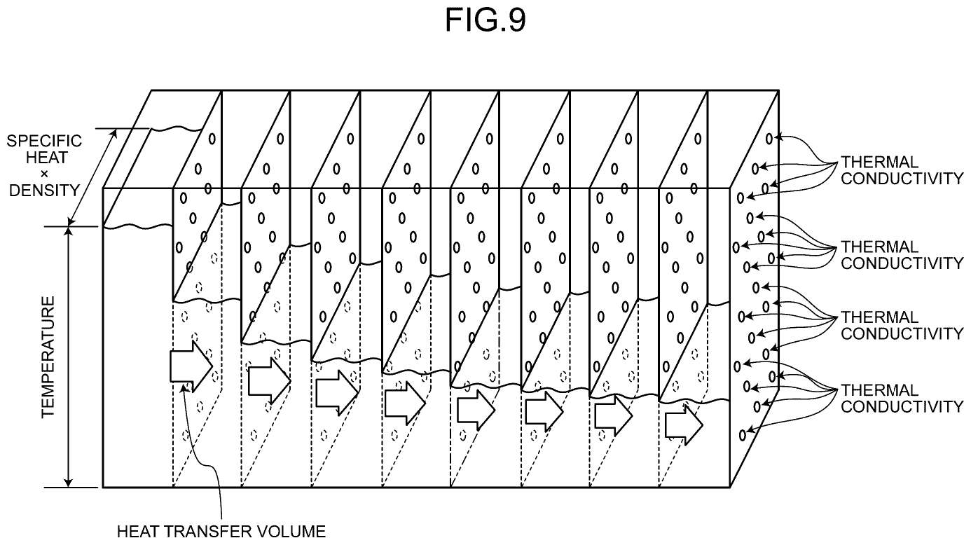

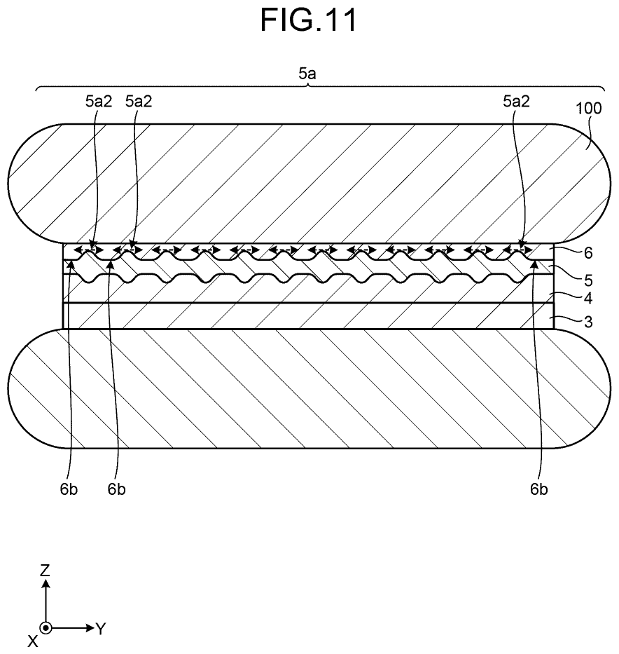

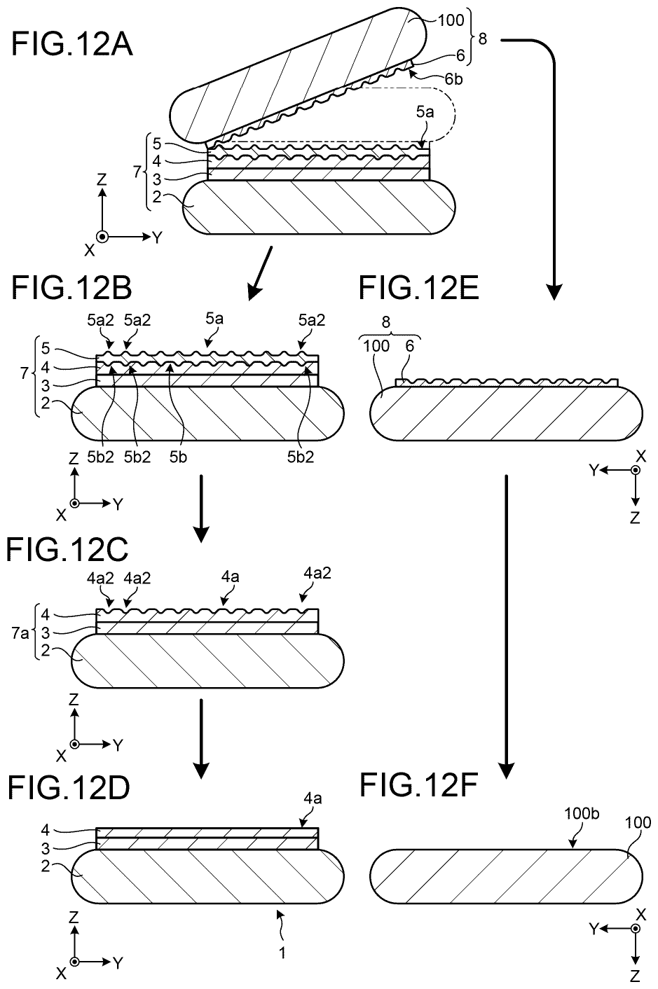

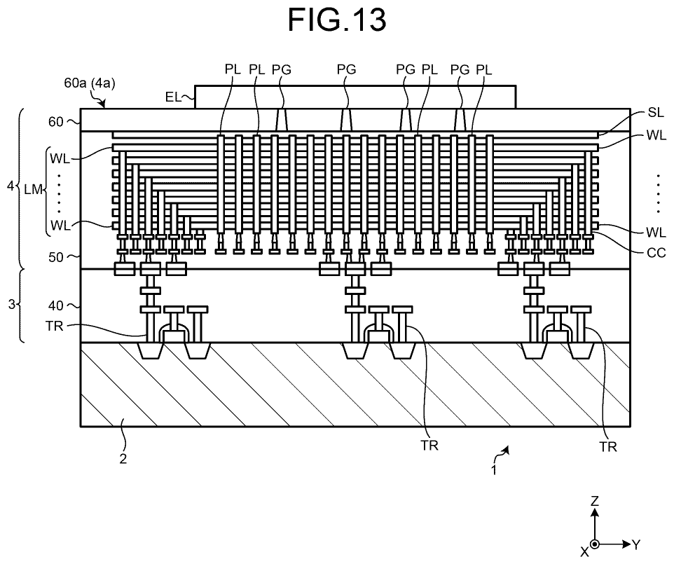

For example, a method for manufacturing a semiconductor device 1 can be performed as illustrated in FIGS. 1 to 13. FIG. 1 is a flowchart illustrating a method for manufacturing the semiconductor device 1. FIGS. 2A to 2F, 3A, 3B, 4A to 4B, 5, 6A to 6C, 10A to 10C, 11, 12A to 12E, and 13 are YZ cross-sectional views illustrating the method for manufacturing the semiconductor device 1. FIG. 3A is an enlarged cross-sectional view of FIG. 2B. FIG. 3B is an enlarged cross-sectional view of FIG. 2E. FIG. 5 is an enlarged cross-sectional view of FIG. 4A. FIG. 13 is an enlarged cross-sectional view corresponding to FIG. 12C. FIG. 11 is a YZ cross-sectional view illustrating generation of stress. FIGS. 7A to 7C are diagrams illustrating temperature distribution of a substrate at the time of laser beam irradiation. FIGS. 8A and 8B are cross-sectional views illustrating a flow of heat of the substrate at the time of laser beam irradiation. FIG. 9 is a diagram for explaining thermal conductivity and thermal diffusivity.

In the method for manufacturing the semiconductor device 1, as illustrated in FIG. 1, processing of a lower substrate (S1 to S2) and processing of an upper substrate (S3 to S4) are performed in parallel, for example. The lower substrate is a substrate disposed on a −Z side at the time of bonding between two substrates to be bonded. The upper substrate is a substrate disposed on a +Z side at the time of bonding between the two substrates to be bonded.

In preparation (S1) of the lower substrate, a substrate (lower substrate) 2 is prepared as illustrated in FIG. 2A. The substrate 2 may be formed by a material containing a semiconductor substantially free of impurities (for example, silicon) as a main component.

In film formation (S2), as illustrated in FIG. 2B, a predetermined device structure is formed on a main surface 2a side (+Z side) of the substrate 2.

For example, a peripheral circuit structure PHC as illustrated in FIG. 3A may be formed. Impurities are introduced into the vicinity of the main surface 2a on the +Z side of the substrate 2 to form a semiconductor region SR. A conductive pattern GT is formed on the main surface 2a of the substrate 2. Thus, a plurality of transistors TR each including the semiconductor region SR and the conductive pattern GT is formed. The peripheral circuit structure PHC including the plurality of transistors TR functions as a peripheral circuit for a memory cell array structure MAR to be described later.

After the predetermined device structure is formed, a film 3 covering the main surface 2a of the substrate 2 is formed by a CVD method or the like. For example, an interlayer insulating film 40 is deposited on the main surface 2a of the substrate 2. The interlayer insulating film 40 may be formed by a material containing an insulator as a main component, or may be formed by a material containing a semiconductor oxide (for example, silicon oxide) as a main component. In addition, holes are processed in the interlayer insulating film 40 along with deposition of the interlayer insulating film 40, and a conductive material is embedded or a conductive pattern is formed, whereby a wiring structure WR electrically connected to the transistor TR is formed. On a main surface 40a on a +Z side of the interlayer insulating film 40, an electrode PD1 electrically connected to the wiring structure WR is formed by plating or the like. The surface of the electrode PD1 and the surface of the interlayer insulating film 40 is substantially flush. It should be noted that the flushness includes having a step with a height equal to or smaller than 1 μm. In FIG. 2B and the subsequent drawings, for the sake of simplicity, a film including the conductive pattern GT, the wiring structure WR, the electrode PD1, and the interlayer insulating film 40 is illustrated and described as the film 3. In addition, the interlayer insulating film 40 occupies most of the film 3 in terms of volume, and thus the film 3 is treated as a film that may be formed by a material containing a semiconductor oxide (for example, silicon oxide) as a main component. Note that the device structure illustrated in FIG. 3A is an example, and is not particularly limited.

In preparation (S3) of the upper substrate, as illustrated in FIG. 2C, a substrate (upper substrate) 100 is prepared. The substrate 100 may be formed by a material containing a semiconductor (for example, silicon) substantially containing no impurities as a main component.

In film formation (S4), as illustrated in FIG. 2D, a film 6 is deposited on a main surface 100b side of the substrate 100 by a CVD method or the like. The film 6 may be formed by any material having a larger infrared light absorption rate than that of the substrate 100. The film 6 may be formed by, for example, a material having a larger absorption rate of a laser wavelength (for example, equal to or more than 9.2 μm and equal to or less than 10.8 μm) suitable for a film 4 to function as a laser absorption layer than that of the substrate 100. The film 6 may be formed by a material removable by wet etching. The film 6 may be formed by a material containing a semiconductor oxide (for example, silicon oxide) as a main component. A film thickness of the film 6 may be any film thickness suitable for functioning as a laser absorption layer, but may be, for example, equal to or more than 0.1 μm and equal to or less than 1 μm.

As illustrated in FIG. 2E, a film 5 is deposited on a −Z side of the film 6 by a CVD method or the like. The film 5 may be formed by any material having a linear expansivity larger than that of the film 6. The film 5 may be formed by any material having thermal conductivity larger than that of the film 6. The film 5 may be formed by any material having thermal diffusivity larger than that of the film 6. The film 5 may be formed by a material containing a semiconductor polycrystalline material (for example, polycrystalline silicon) as a main component, or may be formed by a material containing a semiconductor amorphous material (for example, amorphous silicon) as a main component. The film 5 may be formed by a material containing a semiconductor porous material (for example, porous silicon) as a main component. Note that, in a case where the film 5 is formed by a material containing porous silicon as a main component, the porosity degree may be equal to or more than 40% and equal to or less than 90%, and preferably equal to or more than 50% and equal to or less than 90%. As the porosity degree, a value measured by spectroscopic ellipsometry or a gas adsorption method may be used. A film thickness of the film 5 may be any film thickness suitable for the interface with the film 6 to be a peeling interface, but may be, for example, equal to or more than 0.05 μm and equal to or less than 1 μm, and preferably equal to or more than 0.05 μm and equal to or less than 0.2 μm.

As illustrated in FIG. 2F, the film 4 is deposited on a −Z side of the film 5 by a CVD method or the like.

For example, the film 4 including the memory cell array structure MAR as illustrated in FIG. 3B may be formed. After the insulating film 60 is deposited on the −Z side of the film 5, a conductive film is deposited, and the conductive film is patterned to form a conductive layer SL. The insulating film 60 may be formed by an insulator such as silicon oxide. The conductive layer SL can be formed by a semiconductor imparted with conductivity such as polysilicon containing impurities. Thereafter, an insulating layer and a sacrificial layer (not illustrated) are alternately deposited a plurality of times on a +Z side of the conductive layer SL to form a stacked body LM. The insulating layer may be formed by an insulator such as silicon oxide. The sacrificial layer may be formed by an insulator capable of securing an etching selection ratio to an insulating layer such as silicon nitride. Each insulating layer and each sacrificial layer can be deposited with a substantially similar film thickness.

A resist pattern opened in a linear shape extending in the Y direction is formed on a −Z side of the stacked body LM. Anisotropic etching such as reactive ion etching (RIE) is performed using the resist pattern as a mask to form a groove penetrating the stacked body LM in Y and Z directions. Then, a dividing film (not illustrated) is embedded in the groove. The dividing film may be formed by a material containing an insulator (for example, silicon oxide) as a main component. The dividing film extends in the Y and Z directions on a −X side of the stacked body LM. The dividing film divides the stacked body LM from another stacked body LM on the −X side. In each stacked body LM, the insulating layers and the sacrificial layers are alternately stacked a plurality of times. Each stacked body LM has a substantially rectangular shape with the Y direction as a longitudinal direction in an XY plane view.

A resist pattern in which the formation position of a memory hole is opened is formed on the −Z side of each stacked body LM. Anisotropic etching such as RIE is performed using the resist pattern as a mask to form a memory hole penetrating the stacked body LM and reaching the conductive layer SL.

A block insulating film, a charge storage film, and a tunnel insulating film are sequentially deposited on a side surface and a bottom surface of the memory hole. The block insulating film may be formed by an insulator such as silicon oxide. A portion of the bottom surface of the memory hole in the tunnel insulating film is selectively removed.

A semiconductor film is deposited on the side surface and the bottom surface of the memory hole. The semiconductor film may be formed by a material containing a semiconductor (for example, polysilicon) as a main component. Then, a core member is embedded in the memory hole. The core member may be formed by an insulator such as silicon oxide. Thus, a plurality of columnar bodies PL penetrating the stacked body LM in the Z direction is formed. The plurality of columnar bodies PL is formed so as to be arranged in X and Y directions.

The sacrificial layer of the stacked body LM is removed. A block insulating film is formed on the exposed surface of a gap formed by the removal. The block insulating film may be formed by an insulator such as aluminum oxide. The conductive layer WL is further embedded in the gap. The conductive layer WL may be formed by a material containing a conductive material (for example, a metal such as tungsten) as a main component. Thus, a stacked body LM in which the conductive layers WL and the insulating layers are alternately and repeatedly stacked is formed. A memory cell is formed at a position where the conductive layer WL intersects the semiconductor film of the columnar body PL. That is, a memory cell array structure MAR in which a plurality of memory cells is three-dimensionally arranged is formed.

Further, an interlayer insulating film 50 covering the stacked body LM is further formed. By repeating formation of a resist pattern, slimming, and etching processing, or the like, a staircase structure in which the conductive layers WL are extended stepwise on both sides in the Y direction of the stacked body LM is formed. A conductive plug CC electrically connected to each of the conductive layers WL is formed by forming a hole in the interlayer insulating film 50 and embedding a conductive material, or the like. In addition, holes are processed in the interlayer insulating film 50 along with deposition of the interlayer insulating film 50, and a conductive material is embedded or a conductive pattern is formed, thereby forming a wiring structure WR2 electrically connected to the conductive plug CC. An electrode PD2 electrically connected to the wiring structure WR2 is formed on a main surface 50a on a −Z side of the interlayer insulating film 50 by plating or the like. The surface of the electrode PD2 and the surface of the interlayer insulating film 50 is substantially flush. It should be noted that the flushness includes having a step with a height equal to or smaller than 1 μm. In FIG. 2F and the subsequent drawings, for the sake of simplicity, a film including the memory cell array structure MAR, the conductive plugs CC, the wiring structure WR2, the electrodes PD2, and the interlayer insulating films 50 and 60 will be illustrated and described as the film 4. Further, a portion of the film 4 focused on in the present embodiment is the interlayer insulating film 60, the material of the film 4 is mainly treated as the material of the interlayer insulating film 60. Note that the material of the interlayer insulating film 50 and the material of the interlayer insulating film 60 are substantially the same as each other. Also, the device structure illustrated in FIG. 3B is an example, and is not particularly limited. In addition, although one memory cell array structure MAR is illustrated in FIG. 3B, a plurality of memory cell array structures MAR may be provided.

The film 4 may be formed by substantially the same material as the film 6. The film 4 may be a film that has substantially the same material as that of the film 6 and has different composition from that of the film 6. The film 4 may be formed by any material having a larger infrared light absorption rate than that of the substrate 100. The film 4 may be formed by, for example, a material having a larger absorption rate of a laser wavelength (for example, equal to or more than 9.2 μm and equal to or less than 10.8 μm) suitable for the film 4 to function as a laser absorption layer than that of the substrate 100. The film 6 may be formed by a material containing a semiconductor oxide (for example, silicon oxide) as a main component. A film thickness of the film 4 may be any film thickness suitable for functioning as a laser absorption layer, but may be, for example, equal to or more than 0.1 μm and equal to or less than 1 μm. The film 5, the film 4 and the film 6 may be films that have different composition from that of each other.

As illustrated in FIG. 1, when both the processing of the lower substrate (S1 to S2) and the processing of the upper substrate (S3 to S4) are completed, the upper substrate and the lower substrate are bonded (S5). A main surface 3a (see FIG. 2B) on a +Z side of the film 3 and a main surface 4b (see FIG. 2F) on a −Z side of the film 4 are activated by plasma irradiation or the like, and as illustrated in FIG. 2G, the substrate 2 and the substrate 100 are arranged to face each other in the Z direction so that the main surface 3a and the main surface 4b face each other. As illustrated in FIGS. 2G, 4A, and 5, an XY position of the substrate 2 and an XY position of the substrate 100 are aligned so that an XY position of the electrode PD1 on the main surface 3a corresponds to an XY position of the electrode PD2 on the main surface 4b. As illustrated in FIGS. 4A and 5, the substrate 2 and the substrate 100 are brought close to each other in the Z direction, and the main surface 3a on the substrate 2 side and the main surface 4b on the substrate 100 side are bonded. At this time, atoms of the main surface 3a and atoms of the main surface 4b are bonded by hydrogen bonding or the like, and the substrate 2 and the substrate 100 are in a temporarily bonded state. At this time, a boundary between the film 3 and the film 4 is a bonding face.

Thus, as illustrated in FIG. 1, heat treatment (annealing) at a relatively low temperature is performed (S6). In the heat treatment (annealing), the substrate 2 and the substrate 100 are entirely heated as indicated by dotted arrows in FIG. 4B. In the heat treatment, for example, the substrate 2 and the substrate 100 are each heated to a relatively low temperature (that is, an allowable temperature of the device structure, for example, about 200° C.) for a predetermined time. At this time, the atoms of the main surface 3a and the atoms of the main surface 4b are bonded to each other by a covalent bond or the like as water molecules escape from the interface, and the substrate 2 and the substrate 100 are brought into a state of being finally bonded. Thus, a bonded body CB of the substrate 2 and the substrate 100 is formed. At this time, the electrode PD1 and the electrode PD2 are bonded by direct bonding, the interlayer insulating film 40 and the interlayer insulating film 50 are bonded by direct bonding, and the peripheral circuit structure PHC and the memory cell array structure MAR can be electrically connected.

When S6 illustrated in FIG. 1 is completed, irradiation with a laser beam 200 is performed from the side of the substrate 100 (S7).

The irradiation with the laser beam is performed with the laser beam 200 having a wavelength band (for example, a wavelength band equal to or more than 9.2 μm and equal to or less than 10.8 μm) in which the light absorption rates of the film 6 and the film 4, which are the laser absorption layers, are larger than that of the substrate 100. As the laser beam 200, a pulse laser is used. As the laser beam 200, an infrared laser may be used. As the laser beam 200, a carbon dioxide laser (CO₂ laser) may be used. The absorption of the laser beam 200 occurs depending on an absorption coefficient and a thickness of the substrate or the film, and in the present structure, laser absorption mainly occurs in the film 6 and the film 4 to be the laser absorption layers.

Note that, in a laser irradiation device including a stage and a light source, the light source may gradually move from a center position to an outer peripheral position of the substrate while the stage is rotated. In this case, it is possible to achieve an irradiation pattern of a spot region from the center position toward the outer peripheral position along a spiral trajectory OB (not illustrated). The light source may move from the outer peripheral position toward the center position.

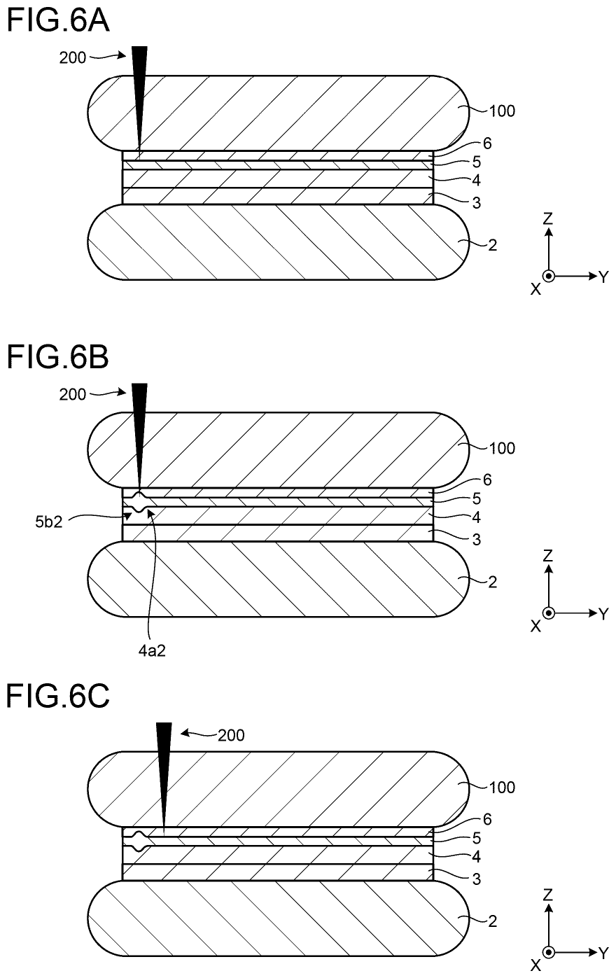

For example, as illustrated in FIG. 6A, an XY plane position to be irradiated with the laser beam 200 of the first irradiation is determined, and a focal point of the laser beam 200 is adjusted to be located in the film 6. The XY plane position to be irradiated may be a start position of the spiral trajectory OB. The absorption rate of the laser beam 200 of the film 6 is larger than the absorption rate of the laser beam 200 of the substrate 100, and the absorption rate of the laser beam 200 of the film 4 is larger than the absorption rate of the laser beam 200 of the substrate 100. Thus, the laser beam 200 applied to the film 6 through the substrate 100 is mainly absorbed in the vicinity of the irradiation portions in the film 6 and the film 4, and locally heats the film 6 and the film 4 at the XY plane positions thereof.

For example, as illustrated in FIGS. 7A and 7B, the temperatures of the film 6 and the film 4 become high at the XY positions thereof due to local heat generation of the film 6 and the film 4. At this time, the thermal conductivity of the film 5 is larger than the thermal conductivity of the film 6, and the thermal conductivity of the film 5 is larger than the thermal conductivity of the film 4. Thus, as illustrated in FIG. 8B, the heat in the film 6 is transmitted to the substrate 100 in the +Z direction and is transmitted to the film 5 in the −Z direction.

Here, as illustrated in FIG. 9, a material having a high thermal conductivity (W/(m·K)) has a large heat flow (W), and a large amount of heat (J) is transferred per temperature gradient per unit time. On the other hand, even if the heat (J) is transferred, the temperature (K) is less likely to increase when the heat capacity (J/K) is large. When the thermal conductivity is relatively larger than the heat capacity (J/K), the temperature (K) tends to increase. That is, when thermal diffusivity (m/s)=thermal conductivity (W/(m·K)/(specific heat (J/(kg·K)×density (kg/m³)) is high, the temperature (K) tends to increase. At this time, when the linear expansion coefficient (1/K) of the film 5 is higher than those of the film 6 and the film 4, a large stress may be generated at the interface between the film 6 and the film 4 due to the difference in linear expansion coefficient.

The thermal diffusivity of the film 5 illustrated in FIG. 7A is larger than the thermal diffusivity of the film 6, and the thermal diffusivity of the film 5 is larger than the thermal diffusivity of the film 4. Accordingly, as illustrated in FIG. 8B, the heat transferred to the film 5 is further transferred in the X and Y directions in the film 5. Thus, a flow of heat that draws the heat in the film 6 to the film 5 side is formed, and as illustrated in FIGS. 7B and 7C, the temperature of the substrate 100 can be suppressed to be equal to or lower than a target temperature Tth, and the temperature of the film 5 can be raised to around a maximum temperature T1.

At this time, the linear expansivity of the film 5 is larger than the linear expansivity of the film 6, and the linear expansivity of the film 5 is larger than the linear expansivity of the film 4. As the temperature of the film 5 rises, the film 5 expands more than the film 6 and the film 4. Accordingly, stress caused by the difference in expansion at the XY plane positions thereof is generated at the interface between the film 5 and the film 6. Thus, as illustrated in FIG. 6B, peeling occurs at the interface between the film 5 and the film 6 at the XY plane positions thereof. Alternatively, peeling may be performed at an interface between the film 5 and the film 4.

As illustrated in FIG. 6C, the XY plane position to be irradiated with the laser beam 200 of the second irradiation is determined to be a position shifted in an XY plane direction from the XY plane position of FIG. 6A, and the focal point of the laser beam 200 is adjusted to be located in the film 6. The position shifted in the XY plane direction from the XY plane position in FIG. 6A may be a position shifted from the start position along the spiral trajectory OB. The absorption rate of the laser beam 200 of the film 6 is larger than the absorption rate of the laser beam 200 of the substrate 100, and the absorption rate of the laser beam 200 of the film 4 is larger than the absorption rate of the laser beam 200 of the substrate 100. Thus, the laser beam 200 with which the film 6 is irradiated through the substrate 100 is absorbed mainly at the irradiation portion in the film 6, and causes the film 6 and the film 4 to locally generate heat (locally heat) at the XY plane positions thereof.

For example, as illustrated in FIGS. 7A and 7B, the temperatures of the film 6 and the film 4 become high at the XY positions thereof due to local heat generation of the film 6 and the film 4. At this time, the thermal conductivity of the film 5 is larger than the thermal conductivity of the film 6, and the thermal conductivity of the film 5 is larger than the thermal conductivity of the film 4. Thus, as illustrated in FIG. 8B, the heat in the film 6 is transmitted to the substrate 100 in the +Z direction and is transmitted to the film 5 in the −Z direction.

The thermal diffusivity of the film 5 is larger than the thermal diffusivity of the film 6, and the thermal diffusivity of the film 5 is larger than the thermal diffusivity of the film 4. Accordingly, as illustrated in FIG. 8B, the heat transferred to the film 5 is further transferred in the X and Y directions in the film 5. Thus, a flow of heat that draws the heat in the film 6 to the film 5 side is formed, and as illustrated in FIGS. 7B and 7C, the temperature of the substrate 100 can be suppressed to be equal to or lower than the target temperature Tth (for example, 600° C.), and the temperature of the film 5 can be raised to around the maximum temperature T1.

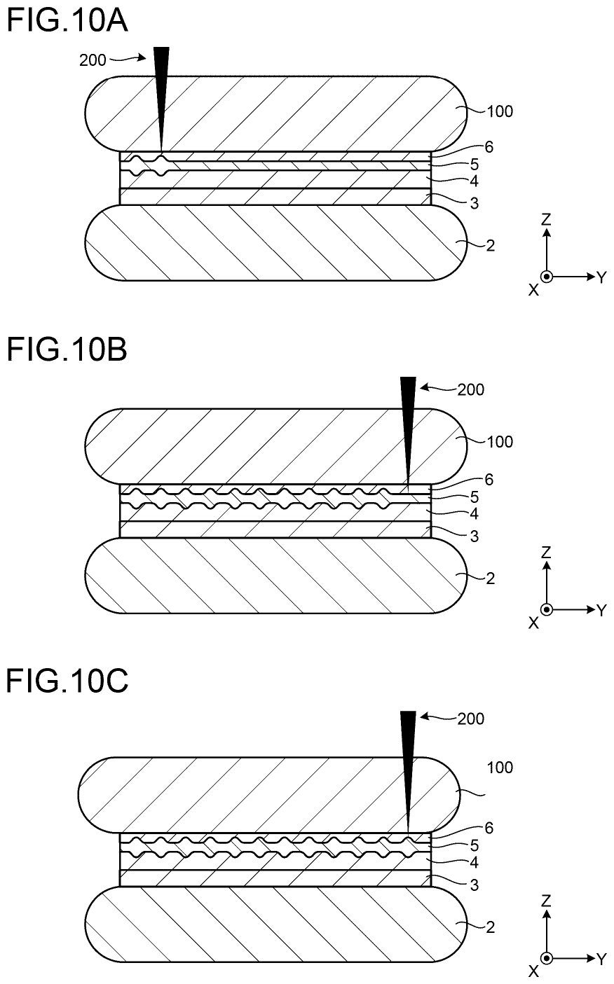

At this time, the linear expansivity of the film 5 is larger than the linear expansivity of the film 6, and the linear expansivity of the film 5 is larger than the linear expansivity of the film 4. As the temperature of the film 5 rises, the film 5 expands more than the film 6 and the film 4. Accordingly, stress caused by the difference in expansion at the XY plane positions thereof is generated at the interface between the film 5 and the film 6. Thus, as illustrated in FIG. 10A, peeling occurs at the interface between the film 5 and the film 6 at the XY plane positions thereof. Alternatively, peeling may be performed at an interface between the film 5 and the film 4.

As illustrated in FIG. 10B, the final XY plane position to be irradiated with the laser beam 200 of the final N-th irradiation is determined, and the focal point of the laser beam 200 is adjusted to be located in the film 4. N is any integer equal to or more than 3. The final XY plane position may be its final position along the spiral trajectory OB. The absorption rate of the laser beam 200 of the film 6 is larger than the absorption rate of the laser beam 200 of the substrate 100, and the absorption rate of the laser beam 200 of the film 4 is larger than the absorption rate of the laser beam 200 of the substrate 100. Thus, the laser beam 200 with which the film 6 is irradiated through the substrate 100 is absorbed mainly at the irradiation portion in the film 6, and causes the film 6 and the film 4 to locally generate heat (locally heat) at the XY plane positions thereof.

For example, as illustrated in FIGS. 7A and 7B, the temperatures of the film 6 and the film 4 become high at the XY positions thereof due to local heat generation of the film 6 and the film 4. At this time, the thermal conductivity of the film 5 is larger than the thermal conductivity of the film 6, and the thermal conductivity of the film 5 is larger than the thermal conductivity of the film 4. Thus, as illustrated in FIG. 8B, the heat in the film 6 is transmitted to the substrate 100 in the +Z direction and is transmitted to the film 5 in the −Z direction.

The thermal diffusivity of the film 5 is larger than the thermal diffusivity of the film 6, and the thermal diffusivity of the film 5 is larger than the thermal diffusivity of the film 4. Accordingly, as illustrated in FIG. 8B, the heat transferred to the film 5 is further transferred in the X and Y directions in the film 5. Thus, a flow of heat that draws the heat in the film 6 to the film 5 side is formed, and as illustrated in FIGS. 7B and 7C, the temperature of the substrate 100 can be suppressed to be equal to or lower than the target temperature Tth, and the temperature of the film 5 can be raised to around the maximum temperature T1.

At this time, the linear expansivity of the film 5 is larger than the linear expansivity of the film 6, and the linear expansivity of the film 5 is larger than the linear expansivity of the film 4. As the temperature of the film 5 rises, the film 5 expands more than the film 6 and the film 4. Accordingly, stress caused by the difference in expansion at the XY plane positions thereof is generated at the interface between the film 5 and the film 6. Thus, as illustrated in FIG. 10C, peeling occurs at the interface from the film 5 and the film 6 at the XY plane positions thereof. Alternatively, peeling may be performed at an interface between the film 5 and the film 4.

The irradiation with the laser beam 200 is performed so that a plurality of spot regions is two-dimensionally distributed in the film 6, and thus a main surface 5a on a +Z side of the film 5 has protrusions 5a2 that are two-dimensionally distributed as illustrated in FIG. 11. On the main surface 5a, the plurality of protrusions 5a2 is arranged apart from each other in the X and Y directions. Thus, as indicated by dotted arrows in FIG. 11, local stress can be generated such that each of the plurality of protrusions 5a2 on the main surface 5a pushes out the film 6 outward in the X and Y directions in the vicinity of a main surface 6b.

Note that, in the interface between the film 5 and the film 6 and the interface between the film 5 and the film 4, local stress is generated at a plurality of positions separated from each other in the X and Y directions. When the temperature of the interface between the film 5 and the film 6 is higher than the temperature of the interface between the film 5 and the film 4, the stress at the interface between the film 5 and the film 6 may be larger than the stress at the interface between the film 5 and the film 4. In FIG. 11, for the sake of simplicity, the local stress generated at the interface between the relatively large films 5 and 6 is selectively illustrated.

Thus, peeling is performed at the interface between the film 5 and the film 6 (S8). In the peeling, as illustrated in FIG. 12A, a stacked body 8 is peeled off from a stacked body 7. In the stacked body 7, the film 3, the film 4, and the film 5 are stacked on the substrate 2. In the stacked body 8, the film 6 is stacked on the substrate 100. For example, since the local stress is generated at the plurality of protrusions 5a2 distributed two-dimensionally, the stacked body 8 is easily peeled off from the stacked body 7 starting from the plurality of protrusions 5a2.

In consideration of the subsequent processing and the like, the peeling surface of the stacked body 7 is processed as illustrated in FIG. 1 (S9). In the stacked body 7, as illustrated in FIG. 12B, the plurality of protrusions 5a2 is distributed in the X and Y directions on the main surface 5a on the +Z side of the film 5, and a plurality of protrusions 5b2 is distributed in the X and Y directions on a main surface 5b on the −Z side of the film 5. The film 5 is removed by dry etching or wet etching.

In a stacked body 7a from which the film 5 has been removed, as illustrated in FIG. 12C, on a main surface 4a on a +Z side of the film 4, a plurality of recesses 4a2 each corresponding to the protrusion 5b2 is distributed in the X and Y directions. The main surface 4a of the film 4 is polished and planarized by a CMP method or the like.

Thus, as illustrated in FIG. 12D, the semiconductor device 1 in which the film 3 and the film 4 are stacked on the substrate 2, and the main surface 4a of the film 4 is planarized is obtained.

For example, as illustrated in FIG. 13, after the planarization, the conductive plug PG electrically connected to the conductive layer SL is formed by forming a hole in a main surface 60a on the +Z side of the interlayer insulating film 60 and embedding a conductive material, or the like. The electrode pattern EL electrically connected to the conductive plug PG is formed on the main surface 60a of the interlayer insulating film 60 by plating or the like. Further, although not illustrated, an electrode pattern EL that bypasses the memory cell array structure MAR and is connected to the peripheral circuit structure PHC is also formed on the main surface 60a of the interlayer insulating film 60. Thus, a power supply, a signal, and the like can be supplied from the outside to the memory cell array structure MAR and the peripheral circuit structure PHC.

Note that the film 4 including the memory cell array structure MAR can be regarded as a chip region for the memory cell array, and the film 3 including the peripheral circuit structure PHC and the substrate 2 can be regarded as a chip region for the peripheral circuit. The semiconductor device 1 has a structure obtained by direct bonding between a chip region for a memory cell array and a chip region for a peripheral circuit. This structure is also called a CMOS directly bonded to array (CBA). In the CBA, the number of chip regions for the memory cell array bonded to the +Z side of the chip region for the peripheral circuit is not limited to one, and may be two or more.

On the other hand, the peeled substrate 100 is reused as illustrated in FIG. 1 (S10). The substrate 100 may be reused as the upper substrate 100 as indicated by a solid arrow in FIG. 2.

In the stacked body 8 immediately after the peeling, as illustrated in FIG. 12D, the main surface 100b on a −Z side of the substrate 100 is covered with the film 6. The film 6 is removed by wet etching.

For example, in a case where the film 6 is formed by a material containing a semiconductor oxide (for example, silicon oxide) as a main component, the film 6 can be easily removed by wet etching while ensuring an etching selection ratio with respect to the material (for example, a semiconductor such as silicon) of the substrate 100.

Thus, as illustrated in FIG. 12E, the substrate 100 is obtained. The substrate 100 illustrated in FIG. 12E is easily reused as, for example, the upper substrate 100. In addition, since polishing by a CMP method or the like is unnecessary, the substrate 100 can be reused in a substantially original state.

Note that the peeled substrate 100 may be reused as the lower substrate 2 as indicated by a dotted arrow in FIG. 1 instead of being reused as the upper substrate 100.

As described above, in the embodiment, after the substrate 2 on which the film 3 is stacked and the substrate 100 on which the film 6, the film 5, and the film 4 are stacked are bonded, the irradiation with the laser beam 200 is performed from the side of the substrate 100 so that the focal point is positioned in the vicinity of the film 6. For example, the film 6 and the film 4 are formed by substantially the same material, and the material of the film 5 is different from the materials of the film 6 and the film 4. The material of the film 5 may have a larger linear expansivity than those of the materials of the film 6 and the film 4. Furthermore, the material of the film 5 may have higher thermal conductivity and a higher thermal diffusivity than those of the materials of the film 6 and the film 4. Thus, light absorption with respect to the laser is performed by the film 6 and the film 4, heat in the film 6 or the like can be drawn to the film 5 side and easily diffused in the film 5, and local stress can be generated at the interface between the film 5 and the film 6 separated from the substrate 100 in the Z direction. As a result, the substrate 100 can be easily separated from the substrate 2 while suppressing thermal damage (for example, lattice distortion due to thermal stress or the like) to the substrate 100. Therefore, the manufacturing yield of the semiconductor device 1 including the substrate 2 can be improved, and the substrate 100 can be easily reused. That is, the substrate 100 can be appropriately separated at the time of manufacturing the semiconductor device 1.

Further, in the embodiment, when the upper substrate 100 is separated, the film 6 is interposed between the peeling interface and the upper substrate 100. That is, the stacked body 8 can be peeled off from the stacked body 7 by performing peeling at the interface between the film 5 and the film 6 separated from the substrate 100 in the Z direction. Thereafter, the film 6 is removed from the stacked body 8 by wet etching. Thus, damage to the substrate 100 at the time of peeling can be suppressed, and damage to the substrate 100 at the time of subsequent removal of the film 6 can be suppressed. As a result, peeling can be performed satisfactorily, and the substrate 100 can be reused in a substantially original state.

For example, as illustrated in FIG. 8A, when light absorption with respect to a laser is performed by the film 6 and the film 4, if most of the heat is directed toward the side of the substrate 100, the substrate 100 is thermally damaged (for example, lattice distortion due to thermal stress or the like). If this thermal damage is large, there is a possibility that the damage cannot be completely recovered even if heat treatment for recovery of the damage is performed thereafter. Thus, it may be difficult to reuse the substrate 100.

On the other hand, in the present embodiment, light absorption with respect to the laser is performed by the film 6 and the film 4, heat in the film 6 or the like can be drawn to the film 5 side and easily diffused in the film 5, and local stress can be generated at the interface between the film 5 and the film 6 separated from the substrate 100 in the Z direction. As a result, the substrate 100 can be easily separated from the substrate 2 while suppressing thermal damage (for example, lattice distortion due to thermal stress or the like) to the substrate 100. Therefore, the manufacturing yield of the semiconductor device 1 including the substrate 2 can be improved, and the substrate 100 can be easily reused.

Note that the separation of the substrate 100 may be performed by peeling at the interface between the film 5 and the film 4 instead of the peeling at the interface between the film 5 and the film 6 (see FIG. 12A).

In addition, as the material of the film 5, any material that efficiently takes heat from the materials of the film 6 and the film 4, easily raises its own temperature, and greatly thermally expands can be applied.

### (Modification 1)

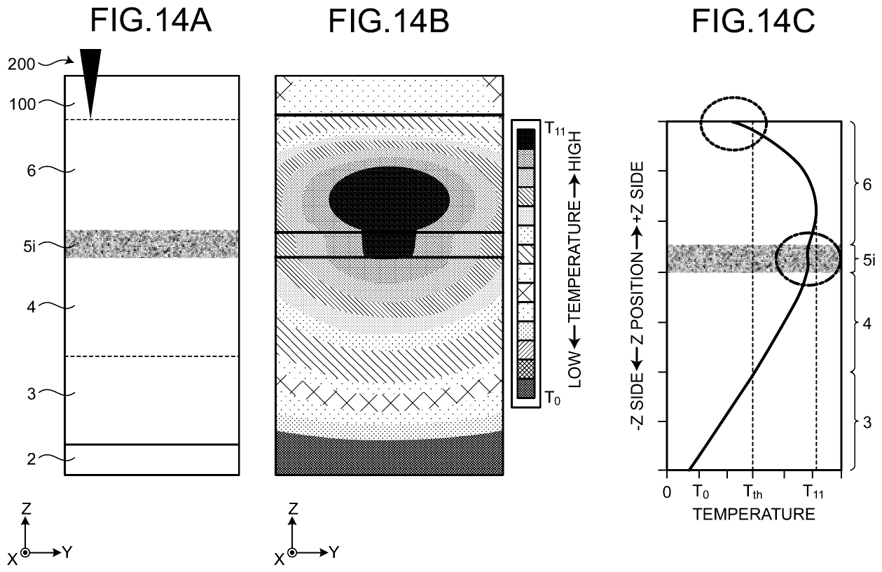

As a first modification of the embodiment, a material of a film 5i may be a material containing a semiconductor nitride (for example, silicon nitride) as a main component as illustrated in FIGS. 14A to 14C. FIGS. 14A to 14C are diagrams illustrating temperature distribution of a substrate at the time of laser beam irradiation according to the first modification of the embodiment. A film thickness of the film 5i may be any film thickness suitable for the interface with the film 6 to be a peeling interface, but may be, for example, equal to or more than 0.05 μm and equal to or less than 1 μm, and preferably equal to or more than 0.05 μm and equal to or less than 0.2 μm.

For example, as illustrated in FIG. 6A, when the irradiation with the laser beam 200 is performed from the side of the substrate 100, as illustrated in FIGS. 14A and 14B, the temperatures of the film 6 and the film 4 become high at the XY positions thereof due to local heat generation of the film 6 and the film 4.

In a case where the materials of the film 6 and the film 4 are materials containing a semiconductor oxide (for example, silicon oxide) as a main component, the material of the film 5i is a material containing a semiconductor nitride (for example, silicon nitride) as a main component, and has higher thermal conductivity than those of the materials of the film 6 and the film 4.

Thus, as illustrated in FIG. 8B, the heat in the film 6 is transmitted to the substrate 100 in the +Z direction and is transmitted to the film 5i in the −Z direction.

In a case where the materials of the film 6 and the film 4 are materials containing a semiconductor oxide (for example, silicon oxide) as a main component, the material of the film 5i illustrated in FIG. 14A is a material containing a semiconductor nitride (for example, silicon nitride) as a main component, and has larger thermal diffusivity than those of the materials of the film 6 and the film 4.

Accordingly, as illustrated in FIG. 8B, the heat transferred to the film 5i is further transferred in the X and Y directions in the film 5i. Thus, a flow of heat that draws the heat in the film 6 to the film 5i side is formed, and as illustrated in FIGS. 14B and 14C, the temperature of the substrate 100 can be suppressed to be equal to or lower than the target temperature Tth, and the temperature of the film 5i can be raised to around a maximum temperature T11.

In a case where the materials of the film 6 and the film 4 are materials containing a semiconductor oxide (for example, silicon oxide) as a main component, the material of the film 5i is a material containing a semiconductor nitride (for example, silicon nitride) as a main component, and has a linear expansivity larger than those of the materials of the film 6 and the film 4.

Accordingly, as the temperature of the film 5i rises, stress due to the difference in linear expansivity is generated at the XY plane positions thereof at each of the interface between the film 5i and the film 6 and the interface between the film 5 and the film 4. Thus, as illustrated in FIG. 6B, the film 5i expands toward the side of the film 6 at the XY plane position thereof, and the film 5i expands toward the side of the film 4.

In this way, also by employing a material containing a semiconductor nitride (for example, silicon nitride) as a main component as the material of the film 5i, the light absorption with respect to the laser is performed by the film 6 and the film 4, the heat in the film 6 and the like can be drawn to the film 5i side and easily diffused in the film 5i, and local stress can be generated at the interface between the film 5 and the film 6 separated from the substrate 100 in the Z direction.

### (Modification 2)

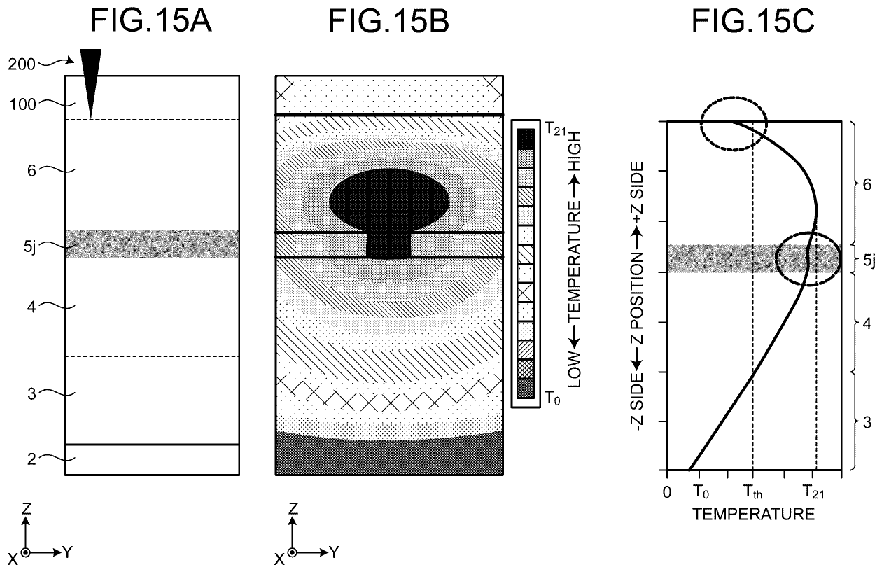

As a second modification of the embodiment, a material of a film 5j may be a material containing a metal oxide (for example, aluminum oxide) as a main component as illustrated in FIGS. 15A to 15C. FIGS. 15A to 15C are diagrams illustrating temperature distribution of a substrate at the time of laser beam irradiation according to the second modification of the embodiment. A film thickness of the film 5j may be any film thickness suitable for the interface with the film 6 to be a peeling interface, but may be, for example, equal to or more than 0.05 μm and equal to or less than 1 μm, and preferably equal to or more than 0.05 μm and equal to or less than 0.2 μm.

For example, as illustrated in FIG. 6A, when the irradiation with the laser beam 200 is performed from the side of the substrate 100, as illustrated in FIGS. 15A and 15B, the temperatures of the film 6 and the film 4 become high at the XY positions thereof due to local heat generation of the film 6 and the film 4.

In a case where the materials of the film 6 and the film 4 are materials containing a semiconductor oxide (for example, silicon oxide) as a main component, the material of the film 5j is a material containing a metal oxide (for example, aluminum oxide) as a main component, and has higher thermal conductivity than those of the materials of the film 6 and the film 4.

Thus, as illustrated in FIG. 8B, the heat in the film 6 is transmitted to the substrate 100 in the +Z direction and is transmitted to the film 5j in the −Z direction.

In a case where the materials of the film 6 and the film 4 are materials containing a semiconductor oxide (for example, silicon oxide) as a main component, the material of the film 5j illustrated in FIG. 15A is a material containing a metal oxide (for example, aluminum oxide) as a main component, and has larger thermal diffusivity than those of the materials of the film 6 and the film 4.

Accordingly, as illustrated in FIG. 8B, the heat transferred to the film 5j is further transferred in the X and Y directions in the film 5j. Thus, a flow of heat that draws the heat in the film 6 to the film 5j side is formed, and as illustrated in FIGS. 15B and 15C, the temperature of the substrate 100 can be suppressed to be equal to or lower than the target temperature Tth, and the temperature of the film 5j can be raised to around a maximum temperature T21.

In a case where the materials of the film 6 and the film 4 are materials containing a semiconductor oxide (for example, silicon oxide) as a main component, the material of the film 5j is a material containing a metal oxide (for example, aluminum oxide) as a main component, and has a linear expansivity larger than those of the materials of the film 6 and the film 4.

Accordingly, as the temperature of the film 5j rises, thermal stress due to the difference in linear expansivity is generated at the XY plane positions thereof at each of the interface between the film 5j and the film 6 and the interface between the film 5 and the film 4. Thus, as illustrated in FIG. 6B, the film 5j expands toward the side of the film 6 at the XY plane position thereof, and the film 5j expands toward the side of the film 4.

In this way, also by employing a material containing a metal oxide (for example, aluminum oxide) as a main component as the material of the film 5j, the light absorption with respect to the laser is performed in the film 6 and the film 4, the heat in the film 6 and the like can be drawn to the film 5j side and easily diffused in the film 5j, and local stress can be generated at the interface between the film 5j and the film 6 separated from the substrate 100 in the Z direction.

### (Modification 3)

As a third modification of the embodiment, although not illustrated, a material of a film 5m may be a material containing a metal nitride (for example, aluminum nitride, tungsten nitride, titanium nitride, or the like) as a main component. A film thickness of the film 5m may be any film thickness suitable for the interface with the film 6 to be a peeling interface, but may be, for example, equal to or more than 0.05 μm and equal to or less than 1 μm, and preferably equal to or more than 0.05 μm and equal to or less than 0.2 μm.

For example, as illustrated in FIG. 6A, when the irradiation with the laser beam 200 is performed from the side of the substrate 100, the temperatures of the film 6 and the film 4 become high at the XY positions thereof due to local heat generation of the film 6 and the film 4.

In a case where the materials of the film 6 and the film 4 are materials containing a semiconductor oxide (for example, silicon oxide) as a main component, the material of the film 5m is a material containing a metal nitride (for example, aluminum nitride) as a main component, and has higher thermal conductivity than those of the materials of the film 6 and the film 4.

Thus, as illustrated in FIG. 8B, the heat in the film 6 is transmitted to the substrate 100 in the +Z direction and is transmitted to the film 5m in the −Z direction.

In a case where the materials of the film 6 and the film 4 are materials containing a semiconductor oxide (for example, silicon oxide) as a main component, the material of the film 5m is a material containing a metal nitride (for example, aluminum nitride, tungsten nitride, titanium nitride, or the like) as a main component, and has larger thermal diffusivity than those of the materials of the film 6 and the film 4.

Accordingly, as illustrated in FIG. 8B, the heat transferred to the film 5m is further transferred in the X and Y directions in the film 5m. Thus, a flow of heat that draws the heat in the film 6 to the film 5m side is formed, the temperature of the substrate 100 can be suppressed to be equal to or lower than the target temperature Tth, and the temperature of the film 5m can be raised to the vicinity of the maximum temperature.

In a case where the materials of the film 6 and the film 4 are materials containing a semiconductor oxide (for example, silicon oxide) as a main component, the material of the film 5m is a material containing a metal nitride (for example, aluminum nitride) as a main component, and has a linear expansivity larger than those of the materials of the film 6 and the film 4.

Accordingly, as the temperature of the film 5m rises, stress due to the difference in linear expansivity is generated at the XY plane positions thereof at each of the interface between the film 5m and the film 6 and the interface between the film 5m and the film 4. Thus, as illustrated in FIG. 6B, the film 5m expands toward the side of the film 6 at the XY plane position thereof, and the film 5m expands toward the side of the film 4.

In this way, also by employing a material containing a metal nitride (for example, aluminum nitride) as a main component as the material of the film 5m, the light absorption with respect to the laser is performed by the film 6 and the film 4, the heat in the film 6 and the like can be drawn to the film 5m side and easily diffused in the film 5m, and local stress can be generated at the interface between the film 5m and the film 6 separated from the substrate 100 in the Z direction.

### (Modification 4)

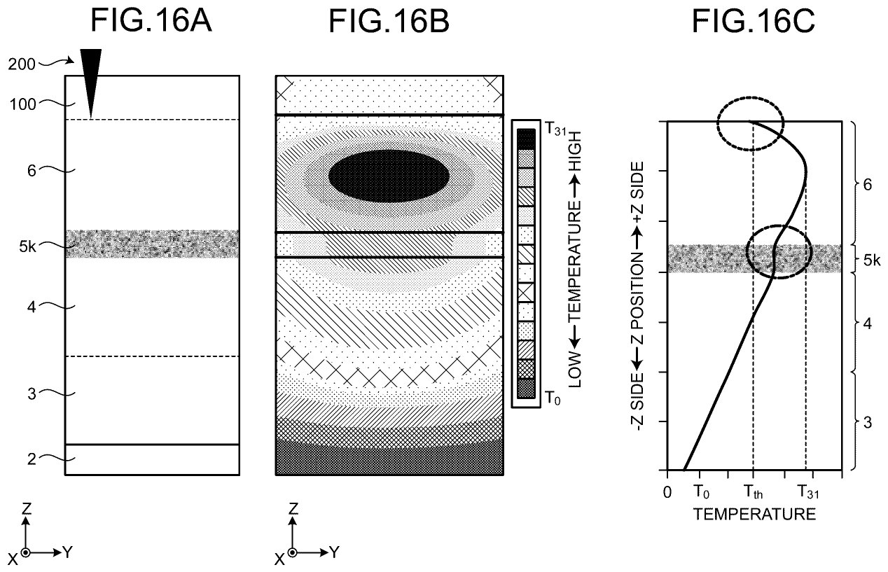

As a fourth modification of the embodiment, a material of a film 5k may be a material containing metal (for example, tungsten, molybdenum, titanium, or the like) as a main component as illustrated in FIGS. 16A to 16C. FIGS. 16A to 16C are diagrams illustrating temperature distribution of a substrate at the time of laser beam irradiation according to the fourth modification of the embodiment. A film thickness of the film 5k may be any film thickness suitable for the interface with the film 6 to be a peeling interface, but may be, for example, equal to or more than 0.05 μm and equal to or less than 1 μm, and preferably equal to or more than 0.05 μm and equal to or less than 0.2 μm.

For example, as illustrated in FIG. 6A, when the irradiation with the laser beam 200 is performed from the side of the substrate 100, as illustrated in FIGS. 16A and 16B, the temperatures of the film 6 and the film 4 become high at the XY positions thereof due to local heat generation of the film 6 and the film 4.

In a case where the materials of the film 6 and the film 4 are materials containing a semiconductor oxide (for example, silicon oxide) as a main component, the material of the film 5k is a material containing a metal (for example, tungsten, molybdenum, titanium, or the like) as a main component, and has higher thermal conductivity than those of the materials of the film 6 and the film 4.

Thus, as illustrated in FIG. 8B, the heat in the film 6 is transmitted to the substrate 100 in the +Z direction and is transmitted to the film 5k in the −Z direction.

In a case where the materials of the film 6 and the film 4 are materials containing a semiconductor oxide (for example, silicon oxide) as a main component, the material of the film 5k illustrated in FIG. 16A is a material containing a metal (for example, tungsten, molybdenum, titanium, or the like) as a main component, and has larger thermal diffusivity than those of the materials of the film 6 and the film 4.

Accordingly, as illustrated in FIG. 8B, the heat transferred to the film 5k is further transferred in the X and Y directions in the film 5k. Thus, a flow of heat that draws the heat in the film 6 to the film 5k side is formed, and as illustrated in FIGS. 16B and 16C, the temperature of the substrate 100 can be suppressed to be equal to or lower than the target temperature Tth, and the temperature of the film 5k can be raised to around a maximum temperature T31.

In a case where the materials of the film 6 and the film 4 are materials containing a semiconductor oxide (for example, silicon oxide) as a main component, the material of the film 5k is a material containing a metal (for example, tungsten, molybdenum, titanium, or the like) as a main component, and has a linear expansivity larger than those of the materials of the film 6 and the film 4.

Accordingly, as the temperature of the film 5k rises, stress due to the difference in linear expansivity is generated at the XY plane positions thereof at each of the interface between the film 5k and the film 6 and the interface between the film 5k and the film 4. Thus, as illustrated in FIG. 6B, the film 5k expands toward the side of the film 6 at the XY plane position thereof, and the film 5k expands toward the side of the film 4.

In this way, also by employing a material containing metal (for example, tungsten, molybdenum, titanium, or the like) as a main component as the material of the film 5k, the light absorption with respect to the laser is performed by the film 6 and the film 4, the heat in the film 6 and the like can be drawn to the film 5k side and easily diffused in the film 5k, and local stress can be generated at the interface between the film 5k and the film 6 separated from the substrate 100 in the Z direction.

### (Modification 5)

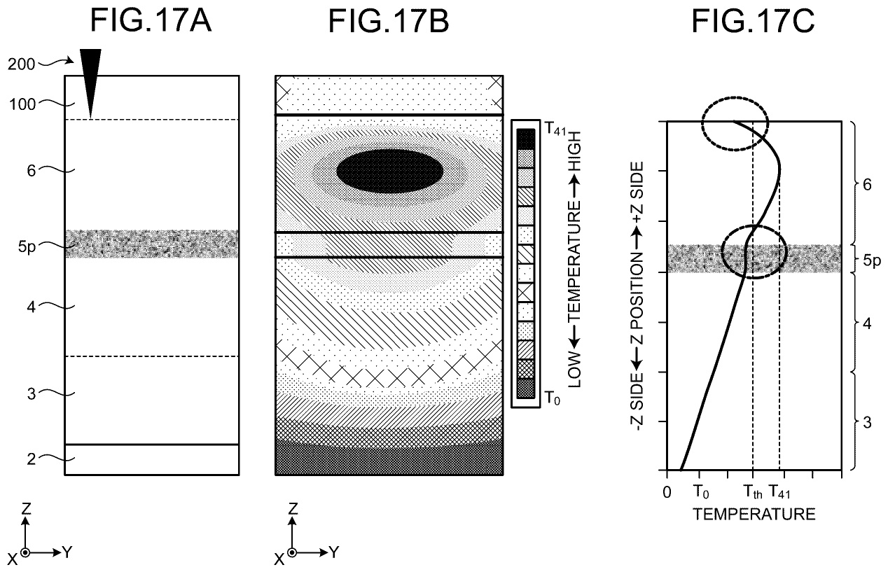

As a fifth modification of the embodiment, a material of a film 5p may be a material containing a metal (for example, copper) having a relatively high thermal conductivity as a main component as illustrated in FIGS. 17A to 17C. FIGS. 17A to 17C are diagrams illustrating temperature distribution of a substrate at the time of laser beam irradiation according to the fifth modification of the embodiment. A film thickness of the film 5p may be any film thickness suitable for the interface with the film 6 to be a peeling interface, but may be, for example, equal to or more than 0.05 μm and equal to or less than 1 μm, and preferably equal to or more than 0.05 μm and equal to or less than 0.5 μm.

For example, as illustrated in FIG. 6A, when the irradiation with the laser beam 200 is performed from the side of the substrate 100, as illustrated in FIGS. 17A and 17B, the temperatures of the film 6 and the film 4 become high at the XY positions thereof due to local heat generation of the film 6 and the film 4.

In a case where the materials of the film 6 and the film 4 are materials containing a semiconductor oxide (for example, silicon oxide) as a main component, the material of the film 5p is a material containing a metal (for example, copper) as a main component, and has higher thermal conductivity than those of the materials of the film 6 and the film 4.

Thus, as illustrated in FIG. 8B, the heat in the film 6 is transmitted to the substrate 100 in the +Z direction and is transmitted to the film 5p in the −Z direction.

In a case where the materials of the film 6 and the film 4 are materials containing a semiconductor oxide (for example, silicon oxide) as a main component, the material of the film 5p illustrated in FIG. 17A is a material containing a metal (for example, copper) as a main component, and has larger thermal diffusivity than those of the materials of the film 6 and the film 4.

Accordingly, as illustrated in FIG. 8B, the heat transferred to the film 5p is further transferred in the X and Y directions in the film 5p. Thus, a flow of heat that draws the heat in the film 6 to the film 5p side is formed, and as illustrated in FIGS. 17B and 17C, the temperature of the substrate 100 can be suppressed to be equal to or lower than the target temperature Tth, and the temperature of the film 5p can be raised to around a maximum temperature T41.

In a case where the materials of the film 6 and the film 4 are materials containing a semiconductor oxide (for example, silicon oxide) as a main component, the material of the film 5p is a material containing a metal (for example, copper) as a main component, and has a linear expansivity larger than those of the materials of the film 6 and the film 4.

Accordingly, as the temperature of the film 5p rises, stress due to the difference in linear expansivity is generated at the XY plane positions thereof at each of the interface between the film 5p and the film 6 and the interface between the film 5p and the film 4. Thus, as illustrated in FIG. 6B, the film 5p expands toward the side of the film 6 at the XY plane position thereof, and the film 5p expands toward the side of the film 4.

In this way, also by employing a material containing a metal (for example, copper) as a main component as the material of the film 5p, the light absorption with respect to the laser is performed by the film 6 and the film 4, the heat in the film 6 and the like can be drawn to the film 5p side and easily diffused in the film 5p, and local stress can be generated at the interface between the film 5p and the film 6 separated from the substrate 100 in the Z direction.

### (Modification 6)

As a sixth modification of the embodiment, a film 5q formed on the −Z side of the film 6 in the film formation (S4) of FIG. 1 may be a film having a plurality of patterns PT_1 to PT_n arranged two-dimensionally. n is any integer equal to or more than 2.

In the film formation (S4) illustrated in FIG. 1, as in the embodiment, the film 6 is deposited on the main surface 100b side of the substrate 100, and the film 5 is deposited on the −Z side of the film 6. For example, the film 5 may be similar to the films 5, 5i, 5m, 5k, and 5p of the above embodiment. Thereafter, a resist pattern corresponding to a plurality of patterns is formed on the −Z side of the film 5, and dry or wet etching is performed using the resist pattern as a mask to form the film 5q having the plurality of patterns PT_1 to PT_n. Thereafter, the film 4 is deposited so as to cover the plurality of patterns PT_1 to PT_n of the film 5q. The subsequent steps are similar to those in the embodiment. Alternatively, after the various films 5 are formed, the patterned film 5 may be formed by what is called a damascene process using lithography, etching, CMP, or the like.

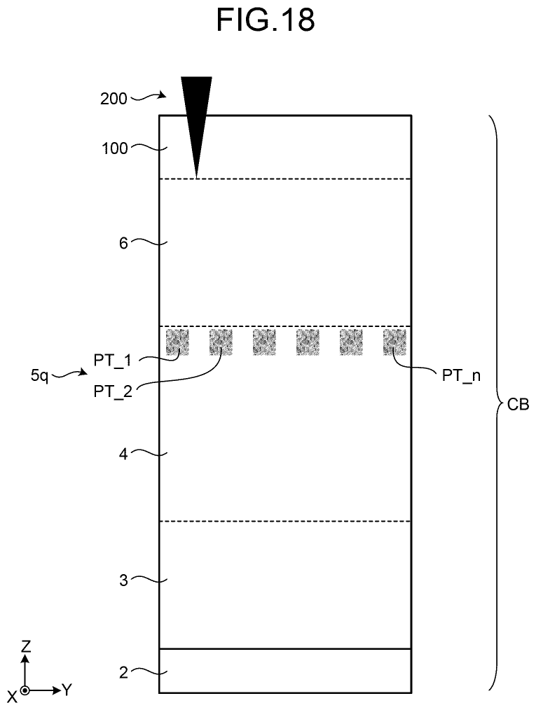

For example, as illustrated in FIG. 18, the stacked body CB (see FIG. 4B) including the film 5q may be irradiated with the laser 200 from the side of the substrate 100. FIG. 18 is a cross-sectional view illustrating a method for manufacturing a semiconductor device according to the sixth modification of the embodiment, and illustrates a step corresponding to FIG. 6A.

The arrangement direction of the plurality of patterns PT_1 to PT_n is arbitrary, but may be a direction along the X direction and/or the Y direction, or may be a direction intersecting the X direction and/or the Y direction. An arrangement pitch of the plurality of patterns PT_1 to PT_n may be uniform along the arrangement direction. An arrangement pitch may be ⅕ of the wavelength of the laser 200, and may be, for example, equal to or less than 2 μm.

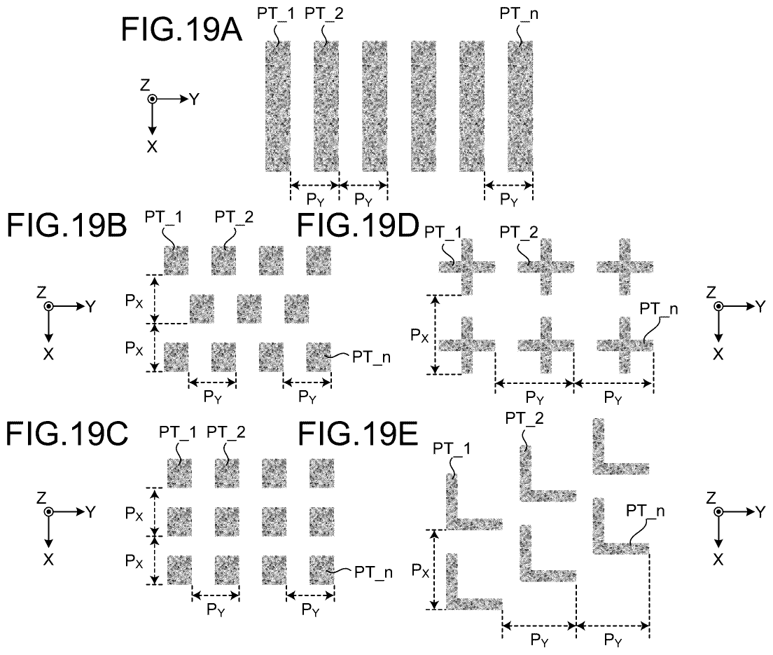

As illustrated in FIG. 19A, each pattern PT may have a linear shape in the XY plane view. FIGS. 19A to 19E are plan views illustrating the method for manufacturing the semiconductor device. Each pattern PT illustrated in FIG. 19A extends in the X direction. The plurality of patterns PT_1 to PT_n is arranged at substantially equal pitches P_{Y} in the Y direction.

As illustrated in FIGS. 19B and 19C, each pattern PT may have a dot shape in the XY plane view. Each pattern PT may have a substantially rectangular dot shape or a substantially circular dot shape. In FIGS. 19B and 19C, a substantially rectangular dot pattern PT is exemplified. An aspect of the arrangement of the patterns PT may be a staggered arrangement as illustrated in FIG. 19B, or a lattice arrangement as illustrated in FIG. 19C. They may be arranged at substantially equal pitches P_{X} in the X direction and may be arranged at substantially equal pitches P_{Y} in the Y direction.

As illustrated in FIG. 19D, each pattern PT may have a cross shape in the XY plane view. Each pattern PT may be a cross-shaped pattern in which a line extending in the X direction and a line extending in the Y direction intersect. The plurality of patterns PT_1 to PT_n may be arranged at substantially equal pitches P_{X} in the X direction and may be arranged at substantially equal pitches P_{Y} in the Y direction.

In addition, each pattern PT may have a T shape. The pattern PT may be a pattern that does not have regularity.

As illustrated in FIG. 19E, each pattern PT may be an asymmetric pattern such as an L shape in the XY plane view. Each pattern PT may be an L-shaped pattern connected to a line extending in the X direction and a line extending in the Y direction at an end. In the plurality of patterns PT_1 to PT_n, the array pitch P_{X} in the X direction may be offset in the X direction, and the array pitch P_{Y} in the Y direction may be constant.

In this way, by including the plurality of two-dimensionally arranged PT_1 to PT_n in the film 5q, when local stress is generated at the interface between the film 5q and the film 6, stress distribution at the interface can be controlled.

### (Modification 7)

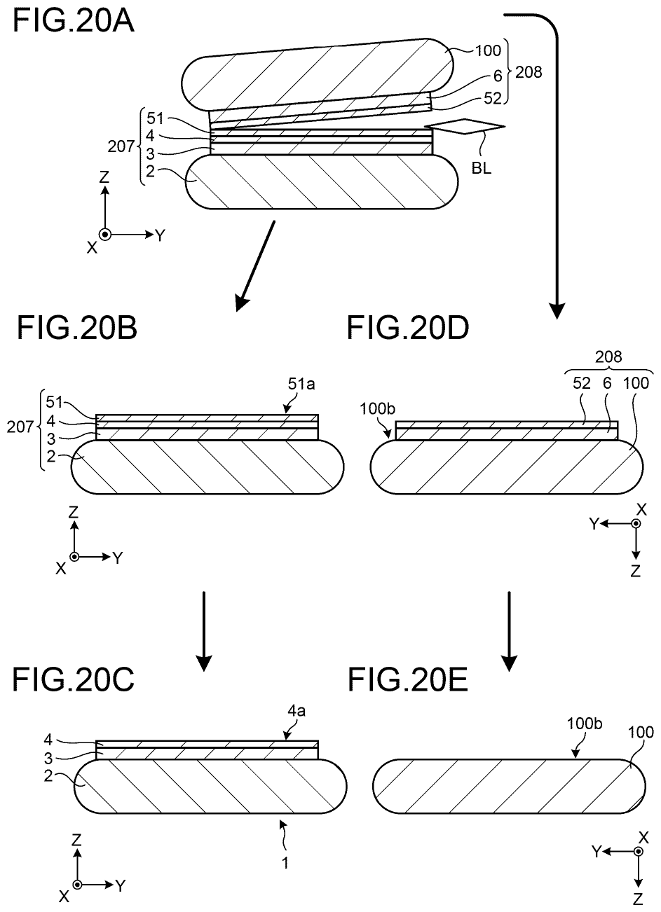

As a seventh modification of the embodiment, separation of the upper substrate 100 may be performed by mechanical peeling as illustrated in FIGS. 20A to 20E. FIGS. 20A to 20E are cross-sectional views illustrating a method for manufacturing the semiconductor device 1 according to the seventh modification of the embodiment.

In a case where mechanical peeling is performed, laser irradiation (S7) illustrated in FIG. 1 is omitted. The point that the processing of the lower substrate (S1 to S2) and the processing of the upper substrate (S3 to S4) are performed in parallel, for example, is similar to the embodiment, but the step of S4 is different from that of the embodiment in the following points.

In the film formation (S4) illustrated in FIG. 1, the film 6 is deposited on the main surface 100b side of the substrate 100. The film 6 may be formed by a material removable by wet etching. The film 6 may be formed by a material containing a semiconductor oxide (for example, silicon oxide) as a main component, or may be formed by a material containing a semiconductor nitride (for example, silicon nitride) as a main component.

The film 5 is deposited on the −Z side of the film 6. At this time, the film 5 may be formed by a material having relatively weak mechanical strength. The film 5 may be formed by a material containing a semiconductor polycrystalline material (for example, polycrystalline silicon) as a main component, or may be formed by a material containing a semiconductor amorphous material (for example, amorphous silicon) as a main component. The film 5 may be formed by a material containing a semiconductor porous material (for example, porous silicon) as a main component. Note that, in a case where the film 5 is formed by a material containing porous silicon as a main component, the porosity degree may be equal to or more than 40% and equal to or less than 90%, and preferably equal to or more than 50% and equal to or less than 90%. As the porosity degree, a value measured by spectroscopic ellipsometry or a gas adsorption method may be used. The subsequent steps are similar to S4 in the embodiment.

The point that, when both the processing (S1 to S2) of the lower substrate and the processing (S3 to S4) of the upper substrate illustrated in FIG. 1 are completed, the upper substrate and the lower substrate are bonded (S5), and heat treatment (S6) is performed is similar to the embodiment.

Thereafter, as illustrated in FIG. 1, peeling is performed (S8). In the peeling, mechanical peeling using the film 5 as a peeling layer is performed, and a stacked body 208 is peeled off from a stacked body 207 as illustrated in FIG. 20A. In the stacked body 207, the film 3, the film 4, and a film 51 are stacked on the substrate 2. The film 51 is a part of the film 5. In the stacked body 208, the film 6 and a film 52 are stacked on the substrate 100. The film 52 is another part of the film 5.

For example, a front end of the blade member BL is inserted near the center of the film 5 in the Z direction. The front end of the blade member BL has a sharp shape forming an acute angle. Since the film 5 is formed by a material having relatively low mechanical strength, the film 5 is divided into the films 51 and 52 in the Z direction by stress due to the insertion of the front end of the blade member BL.

In consideration of the subsequent processing and the like, the peeling surface of the stacked body 207 is processed as illustrated in FIG. 1 (S9). In the stacked body 207 illustrated in FIG. 20B, a main surface 51a on a +Z side of the film 51 is a rough surface due to the influence of mechanical peeling. The film 51 is removed by dry etching or wet etching.

Thus, as illustrated in FIG. 20C, the semiconductor device 1 in which the film 3 and the film 4 are stacked on the substrate 2 and the main surface 4a of the film 4 is flat is obtained.

On the other hand, the peeled substrate 100 is reused as illustrated in FIG. 1 (S10). The substrate 100 may be reused as the upper substrate 100 as indicated by a solid arrow in FIG. 2.

In the stacked body 208 immediately after the peeling, as illustrated in FIG. 20D, the main surface 100b on the −Z side of the substrate 100 is covered with the film 6 and the film 52. The film 6 is removed by wet etching, and accordingly, the film 52 is also removed.

For example, in a case where the film 6 is formed by a material containing a semiconductor oxide (for example, silicon oxide) as a main component, the film 6 can be easily removed by wet etching while ensuring an etching selection ratio with respect to the material (for example, a semiconductor such as silicon) of the substrate 100. Alternatively, in a case where the film 6 is formed by a material containing a semiconductor nitride (for example, silicon nitride) as a main component, the film 6 can be easily removed by wet etching while ensuring an etching selection ratio with respect to the material of the substrate 100 (for example, a semiconductor such as silicon).

Thus, as illustrated in FIG. 20E, the substrate 100 is obtained. The substrate 100 illustrated in FIG. 20E is easily reused as, for example, the upper substrate 100. In addition, since polishing by a CMP method or the like is unnecessary, the substrate 100 can be reused in a substantially original state.

Also in such processing, when the upper substrate 100 is separated, the film 6 is interposed between the peeling interface and the upper substrate 100. That is, peeling is performed using the film 5 separated from the substrate 100 in the Z direction as a peeling layer, and the stacked body 207 can be peeled off from the stacked body 208. Thereafter, the film 6 is removed from the stacked body 208 by wet etching. Thus, damage to the substrate 100 at the time of peeling can be suppressed, and damage to the substrate 100 at the time of subsequent removal of the film 6 can be suppressed. As a result, peeling can be performed satisfactorily, and the substrate 100 can be reused in a substantially original state.

### (Modification 8)

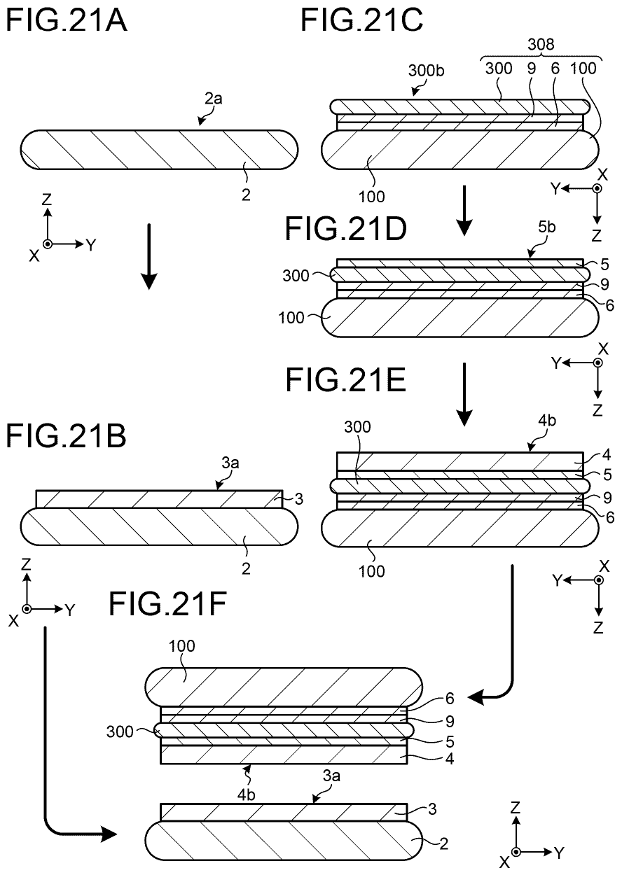

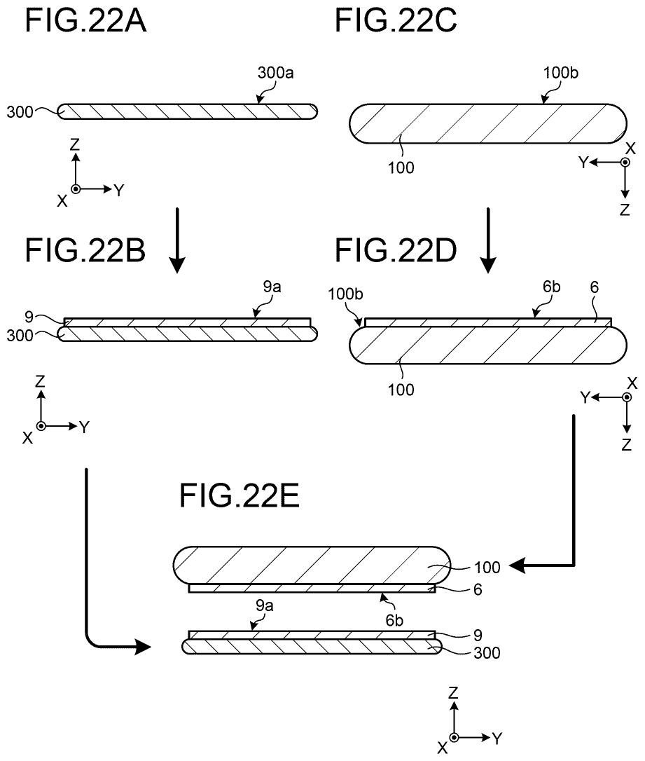

As an eighth modification of the embodiment, as illustrated in FIGS. 21A to 24E, a process of interposing a sacrificial substrate 300 between the peeling interface and the upper substrate 100 may be performed. FIGS. 21A to 21 F, FIGS. 22A to 22E, FIGS. 23A to 23D, and FIGS. 24A to 24E are YZ cross-sectional views illustrating the method for manufacturing the semiconductor device 1.

In the preparation (S1) of the lower substrate, a stacked body 308 including the substrate (lower substrate) 2 is prepared. In S1, the steps illustrated in FIGS. 21A to 21B and the steps illustrated in FIGS. 21C to 21D are performed in parallel, for example.

The preparation (S1) of the lower substrate is performed as in the embodiment (see FIG. 2A) as illustrated in FIG. 21A.

The film formation (S2) is performed in the same manner as in the embodiment (see FIG. 2B) as illustrated in FIG. 21B.

In the preparation (S3) of the upper substrate, as illustrated in FIG. 21C, the stacked body 308 including the substrate (upper substrate) 100 is prepared. The stacked body 308 is formed as illustrated in FIGS. 22A to 22E. In S3, the steps illustrated in FIGS. 22A to 22B and the steps illustrated in FIGS. 22C to 22D may be performed in parallel.

In the process illustrated in FIG. 22A, the sacrificial substrate 300 is prepared. The sacrificial substrate 300 may be formed by a material containing a semiconductor (for example, silicon) substantially containing no impurities as a main component. The sacrificial substrate 300 is a substrate that is not reused and is thinner than the substrate 100.

In the step illustrated in FIG. 22B, a film 9 is deposited on a main surface 300a side on a +Z side of the sacrificial substrate 300 by the CVD method or the like. The film 9 is a dummy film and can be formed by any material.

In the step illustrated in FIG. 22C, a substrate (upper substrate) 100 is prepared. The substrate 100 may be formed by a material containing a semiconductor (for example, silicon) substantially containing no impurities as a main component.

In the step illustrated in FIG. 22D, the film 6 is deposited on the main surface 100b side of the substrate 100 by a CVD method or the like. The film 6 may be similar to the film 6 of the embodiment.

When both the step illustrated in FIG. 22B and the step illustrated in FIG. 22D are completed, the sacrificial substrate 300 and the substrate 100 are bonded. A main surface 9a (see FIG. 22B) on a +Z side of the film 9 and the main surface 6b (see FIG. 22D) on the −Z side of the film 6 are activated by plasma irradiation or the like, and as illustrated in FIG. 22E, the sacrificial substrate 300 and the substrate 100 are arranged to face each other in the Z direction so that the main surface 9a and the main surface 6b face each other. As illustrated in FIG. 21C, the sacrificial substrate 300 and the substrate 100 are brought close to each other in the Z direction, and the main surface 9a on the sacrificial substrate 300 side and the main surface 6b on the substrate 100 side are bonded. At this time, atoms of the main surface 9a and atoms of a main surface 9b are bonded by hydrogen bonding or the like, and the sacrificial substrate 300 and the substrate 100 are temporarily bonded. Thus, the stacked body 308 in which the film 9, the film 6, and the sacrificial substrate 300 are stacked is formed on the substrate 100.

In the film formation (S4), as illustrated in FIG. 21D, the film 5 is deposited on a main surface 300b side on a −Z-side of the stacked body 308 by a CVD method or the like. The film 5 may be similar to the films 5, 5i, 5j, 5m, 5k, 5p, and 5q of the embodiment.

As illustrated in FIG. 21E, the film 4 is deposited on the −Z side of the film 5 by a CVD method or the like. The film 4 may be similar to the film 4 of the embodiment.

As illustrated in FIG. 1, when both the processing of the lower substrate (S1 to S2) and the processing of the upper substrate (S3 to S4) are completed, the upper substrate and the lower substrate are bonded (S5). The main surface 3a (see FIG. 21B) on the +Z side of the film 3 and the main surface 4b (see FIG. 21E) on the −Z side of the film 4 are activated by plasma irradiation or the like, and as illustrated in FIG. 21F, the substrate 2 and the substrate 100 are arranged to face each other in the Z direction so that the main surface 3a and the main surface 4b face each other. The substrate 2 and the substrate 100 are brought close to each other in the Z direction, and the main surface 3a on the substrate 2 side and the main surface 4b on the substrate 100 side are bonded. At this time, atoms of the main surface 3a and atoms of the main surface 4b are bonded by hydrogen bonding or the like, and the substrate 2 and the substrate 100 are in a temporarily bonded state.

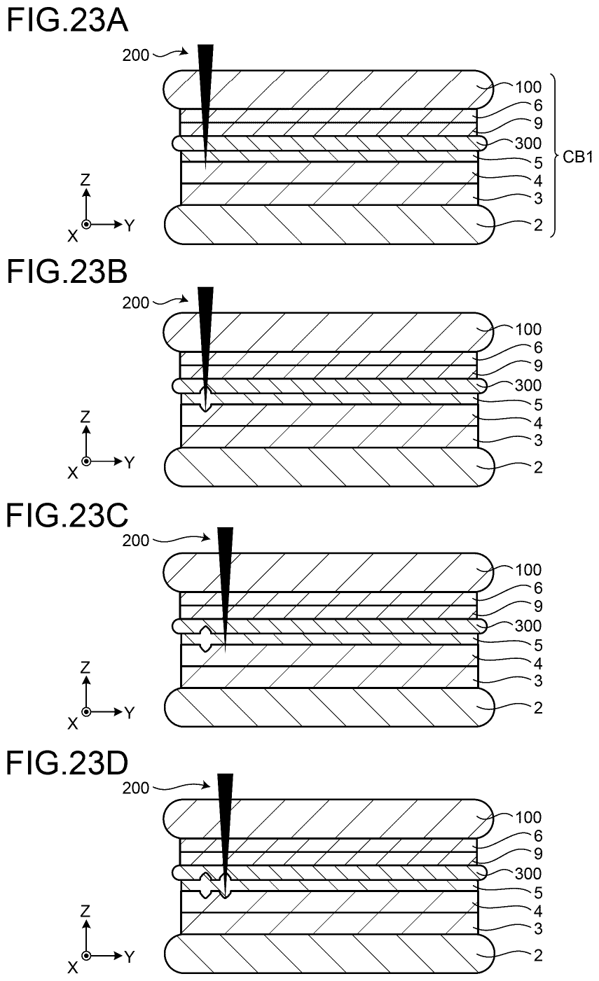

Thereafter, heat treatment (annealing) at a relatively low temperature is performed (S6), and water molecules escape from the interface, so that the atoms of the main surface 3a and the atoms of the main surface 4b are bonded by covalent bonding or the like, and the substrate 2 and the substrate 100 are brought into a state of being finally bonded. Thus, as illustrated in FIG. 23A, the bonded body CB1 of the substrate 2 and the substrate 100 is formed.

When S6 illustrated in FIG. 1 is completed, irradiation with a laser beam 200 is performed from the side of the substrate 100 (S7).

For example, as illustrated in FIG. 23A, the XY plane position to be irradiated with the laser beam 200 of the first irradiation is determined, and the focal point of the laser beam 200 is adjusted to be located in the film 4. The laser beam 200 applied to the film 4 through the substrate 100, the film 6, the film 9, and the sacrificial substrate 300 is efficiently absorbed in the vicinity of the irradiation portion in the film 4, and locally generates heat (locally heats) in the film 4 at the XY plane positions thereof.

Thus, as illustrated in FIG. 23B, the film 5 expands toward the side of the sacrificial substrate 300 at the XY plane position thereof, and the film 5 expands toward the side of the film 4.

As illustrated in FIG. 23C, the XY plane position to be irradiated with the second irradiation laser beam 200 is determined to be a position shifted in an XY plane direction from the XY plane position in FIG. 23A, and the focal point of the laser beam 200 is adjusted to be located in the film 4. The laser beam 200 with which the film 4 is irradiated through the substrate 100, the film 6, the film 9, and the sacrificial substrate 300 is efficiently absorbed at the irradiation portion in the film 4, and locally generates heat (locally heats) in the film 4 at the XY plane positions thereof.

Thus, as illustrated in FIG. 23D, the film 5 expands toward the side of the sacrificial substrate 300 at the XY plane position thereof, and the film 5 expands toward the side of the film 4.

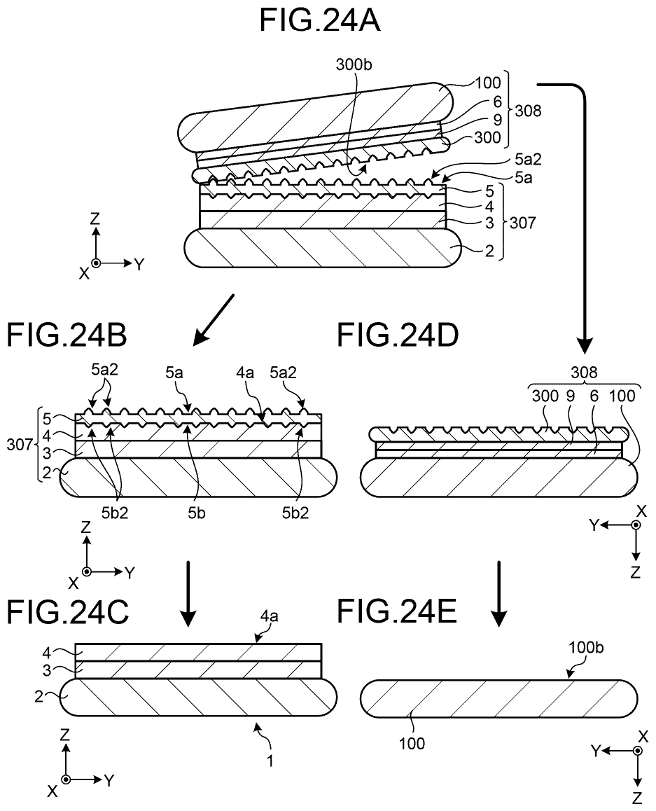

Similarly, when the final Nth irradiation laser beam 200 is applied, as illustrated in FIG. 24A, the main surface 5a on the +Z side of the film 5 has protrusions 5a2 that are two-dimensionally distributed. Thus, local stress can be generated such that each of the plurality of protrusions 5a2 on the main surface 5a pushes out the sacrificial substrate 300 outward in the X and Y directions in the vicinity of the main surface 300b.

Thus, peeling is performed at the interface between the film 5 and the sacrificial substrate 300 (S8). In the peeling, as illustrated in FIG. 24A, the stacked body 308 is peeled off from a stacked body 307. In the stacked body 307, the film 3, the film 4, and the film 5 are stacked on the substrate 2. In the stacked body 308, the film 6, the film 9, and the sacrificial substrate 300 are stacked on the substrate 100. For example, since the local stress is generated at the plurality of protrusions 5a2 distributed two-dimensionally, the stacked body 308 is easily peeled off from the stacked body 307 starting from the plurality of protrusions 5a2.

In consideration of the subsequent processing and the like, the peeling surface of the stacked body 307 is processed as illustrated in FIG. 1 (S9). In the stacked body 307, as illustrated in FIG. 24B, the plurality of protrusions 5a2 is distributed in the X and Y directions on the main surface 5a on the +Z side of the film 5, and the plurality of protrusions 5b2 is distributed in the X and Y directions on the main surface 5b on the −Z side of the film 5. The film 5 is removed by dry etching or wet etching.

In a stacked body 307a from which the film 5 has been removed, a plurality of recesses each corresponding to the protrusion 5b2 is distributed in the X and Y directions on the main surface 4a on the +Z side of the film 4. The main surface 4a of the film 4 is polished and planarized by a CMP method or the like.

Thus, as illustrated in FIG. 24C, the semiconductor device 1 in which the film 3 and the film 4 are stacked on the substrate 2, and the main surface 4a of the film 4 is planarized is obtained.

On the other hand, the peeled substrate 100 is reused as illustrated in FIG. 1 (S10). The substrate 100 may be reused as the upper substrate 100 as indicated by a solid arrow in FIG. 2.

In the stacked body 308 immediately after the peeling, as illustrated in FIG. 24D, the main surface 100b on the −Z side of the substrate 100 is covered with the film 6, the film 9, and the sacrificial substrate 300. The film 6 is removed by wet etching, and accordingly, the film 9 and the sacrificial substrate 300 are also removed.

For example, in a case where the film 6 is formed by a material containing a semiconductor oxide (for example, silicon oxide) as a main component, the film 6 can be easily removed by wet etching while ensuring an etching selection ratio with respect to the material (for example, a semiconductor such as silicon) of the substrate 100. Accordingly, the film 9 and the sacrificial substrate 300 are also removed.

Thus, as illustrated in FIG. 24E, the substrate 100 is obtained. The substrate 100 illustrated in FIG. 24E is easily reused as, for example, the upper substrate 100. In addition, since polishing by a CMP method or the like is unnecessary, the substrate 100 can be reused in a substantially original state.

Also by such processing, when the upper substrate 100 is separated, the film 6, the film 9, and the sacrificial substrate 300 are interposed between the peeling interface and the upper substrate 100. That is, peeling can be performed at the interface between the film 5 separated from the substrate 100 in the Z direction and the sacrificial substrate 300 to peel the stacked body 307 from the stacked body 308. Thereafter, the film 6 is removed from the stacked body 308 by wet etching, and accordingly, the film 9 and the sacrificial substrate 300 are also removed. Thus, damage to the substrate 100 at the time of peeling can be suppressed, and damage to the substrate 100 at the time of removing the film 6, the film 9, and the sacrificial substrate 300 thereafter can be suppressed. As a result, peeling can be performed satisfactorily, and the substrate 100 can be reused in a substantially original state.

### (Modification 9)

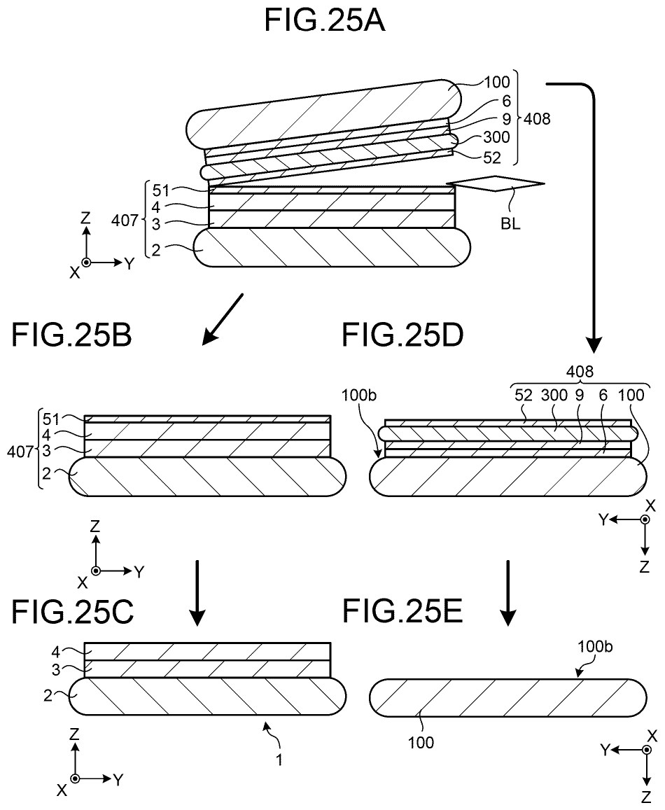

As a ninth modification of the embodiment, separation of the upper substrate 100 in the eighth modification of the embodiment may be performed by mechanical peeling as illustrated in FIGS. 25A to 25E. FIGS. 25A to 25E are cross-sectional views illustrating a method for manufacturing the semiconductor device 1 according to the ninth modification of the embodiment.

In a case where mechanical peeling is performed, laser irradiation (S7) illustrated in FIG. 1 is omitted. The point that the processing of the lower substrate (S1 to S2) and the processing of the upper substrate (S3 to S4) are performed in parallel, for example, is similar to the seventh modification of the embodiment, but the step of S4 is different from the seventh modification of the embodiment in the following points.

In the film formation (S4) illustrated in FIG. 1, the film 6 is deposited on the main surface 100b side of the substrate 100 in the step illustrated in FIG. 22D. The film 6 may be formed by a material removable by wet etching. The film 6 may be formed by a material containing a semiconductor oxide (for example, silicon oxide) as a main component, or may be formed by a material containing a semiconductor nitride (for example, silicon nitride) as a main component.

In the step illustrated in FIG. 21D, the film 5 is deposited on the −Z side of the sacrificial substrate 300. At this time, the film 5 may be formed by a material having relatively weak mechanical strength. The film 5 may be formed by a material containing a semiconductor polycrystalline material (for example, polycrystalline silicon) as a main component, may be formed by a material containing a semiconductor amorphous material (for example, amorphous silicon) as a main component, or may be formed by a material containing a semiconductor porous material (for example, porous silicon) as a main component. Note that, in a case where the film 5 is formed by a material containing porous silicon as a main component, the porosity degree may be equal to or more than 40% and equal to or less than 90%, and preferably equal to or more than 50% and equal to or less than 908. As the porosity degree, a value measured by spectroscopic ellipsometry or a gas adsorption method may be used. The subsequent steps are similar to S4 in the seventh modification of the embodiment.

The point that, when both the processing (S1 to S2) of the lower substrate and the processing (S3 to S4) of the upper substrate illustrated in FIG. 1 are completed, the upper substrate and the lower substrate are bonded (S5), and heat treatment (S6) is performed is similar to the seventh modification of the embodiment.

Thereafter, as illustrated in FIG. 1, peeling is performed (S8). In the peeling, mechanical peeling using the film 5 as a peeling layer is performed, and a stacked body 407 is peeled off from a stacked body 408 as illustrated in FIG. 25A. In the stacked body 407, the film 3, the film 4, and the film 51 are stacked on the substrate 2. The film 51 is a part of the film 5. In the stacked body 408, the film 6, the film 9, the sacrificial substrate 300, and the film 52 are stacked on the substrate 100. The film 52 is another part of the film 5.

For example, a front end of the blade member BL is inserted near the center of the film 5 in the Z direction. The front end of the blade member BL has a sharp shape forming an acute angle. Since the film 5 is formed by a material having relatively low mechanical strength, the film 5 is divided into the films 51 and 52 in the Z direction by stress due to the insertion of the front end of the blade member BL.

In consideration of the subsequent processing and the like, the peeling surface of the stacked body 407 is processed as illustrated in FIG. 1 (S9). In the stacked body 407 illustrated in FIG. 25B, the main surface 51a on the +Z side of the film 51 is a rough surface due to the influence of mechanical peeling. The film 51 is removed by dry etching or wet etching.

Thus, as illustrated in FIG. 25C, the semiconductor device 1 in which the film 3 and the film 4 are stacked on the substrate 2 and the main surface 4a of the film 4 is flat is obtained.

On the other hand, the peeled substrate 100 is reused as illustrated in FIG. 1 (S10). The substrate 100 may be reused as the upper substrate 100 as indicated by a solid arrow in FIG. 2.

In the stacked body 208 immediately after the peeling, as illustrated in FIG. 25D, the main surface 100b on the −Z side of the substrate 100 is covered with the film 6 and the film 52. The film 6 is removed by wet etching, and accordingly, the film 9, the sacrificial substrate 300, and the film 52 are also removed.

For example, in a case where the film 6 is formed by a material containing a semiconductor oxide (for example, silicon oxide) as a main component, the film 6 can be easily removed by wet etching while ensuring an etching selection ratio with respect to the material (for example, a semiconductor such as silicon) of the substrate 100. Alternatively, in a case where the film 6 is formed by a material containing a semiconductor nitride (for example, silicon nitride) as a main component, the film 6 can be easily removed by wet etching while ensuring an etching selection ratio with respect to the material of the substrate 100 (for example, a semiconductor such as silicon). Accordingly, the film 9, the sacrificial substrate 300, and the film 52 are also removed.

Thus, as illustrated in FIG. 25E, the substrate 100 is obtained. The substrate 100 illustrated in FIG. 25E is easily reused as, for example, the upper substrate 100. In addition, since polishing by a CMP method or the like is unnecessary, the substrate 100 can be reused in a substantially original state.

Also in such processing, when the upper substrate 100 is separated, the film 6, the film 9, and the sacrificial substrate 300 are interposed between the peeling interface and the upper substrate 100. That is, peeling is performed using the film 5 separated from the substrate 100 in the Z direction as a peeling layer, and the stacked body 407 can be peeled off from the stacked body 408. Thereafter, the film 6 is removed from the stacked body 408 by wet etching, and accordingly, the film 9 and the sacrificial substrate 300 are also removed. Thus, damage to the substrate 100 at the time of peeling can be suppressed, and damage to the substrate 100 at the time of removing the film 6, the film 9, and the sacrificial substrate 300 thereafter can be suppressed. As a result, peeling can be performed satisfactorily, and the substrate 100 can be reused in a substantially original state.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, the method comprising:
preparing a first substrate provided with a first film;
forming a second film on or above a second substrate;
forming a third film on or above the second film;
forming a fourth film on or above the third film;
forming a stacked body by bonding a main surface of the first film and a main surface of the fourth film;
performing irradiation with a laser beam from a side of the second substrate of the stacked body; and
separating the second substrate in a state of including at least portion of the second film, wherein
the second film and the fourth film each includes a first material, and
the third film includes a second material different from the first material,
the second film and the third film have different composition,
the fourth film and the third film have different composition.

2. The method for manufacturing a semiconductor device according to claim 1, wherein
a linear expansivity of the second material is larger than a linear expansivity of the first material.

3. The method for manufacturing a semiconductor device according to claim 1, wherein
thermal conductivity of the second material is higher than thermal conductivity of the first material.

4. The method for manufacturing a semiconductor device according to claim 1, wherein
thermal diffusivity of the second material is larger than thermal diffusivity of the first material.

5. The method for manufacturing a semiconductor device according to claim 1, wherein
the first material includes a semiconductor oxide, and
the second material includes, as a main component, a material including at least one of a semiconductor, a semiconductor nitride, a metal, a metal oxide, or a metal nitride.

6. The method for manufacturing a semiconductor device according to claim 5, wherein
the first substrate and the second substrate are silicon wafer, and
a wavelength of the laser beam is between 9.2 μm and 10.8 μm.

7. The method for manufacturing a semiconductor device according to claim 5, wherein
the second material includes at least one of a polycrystalline material of a semiconductor or an amorphous material of a semiconductor.

8. The method for manufacturing a semiconductor device according to claim 7, wherein
the second material includes at least one of polysilicon or amorphous silicon.

9. The method for manufacturing a semiconductor device according to claim 1, wherein
the third film has repeated patterns when seen in plan view.

10. The method for manufacturing a semiconductor device according to claim 9, wherein
the pattern has a linear shape, a dot shape, a cross shape, an L shape, and a T shape in plan view.

11. The method for manufacturing a semiconductor device according to claim 1, the method comprising:
before forming a second film on or above a second substrate;
removing a fifth film from the second substrate;
wherein the fifth film includes the first material and the fifth film and the third film have different composition.

12. The method for manufacturing a semiconductor device according to claim 11, wherein
the removing the fifth film includes
wet-etching the fifth film.

13. A semiconductor device comprising:
a first substrate;
a first film disposed above the first substrate;
a second film disposed on the first film; and
a third film disposed on the second film, wherein
each of the first film and the third film includes a first material,
the second film includes a second material different from the first material,
the first film and the second film have different composition,
the third film and the second film have different composition, and
a linear expansivity of the second material is larger than a linear expansivity of the first material.

14. The semiconductor device according to claim 13, wherein
the first material includes semiconductor oxide, and
the second material includes at least one of polycrystalline semiconductor and amorphous semiconductor.

15. The semiconductor device according to claim 14 further comprising:
a second substrate arranged above the third film.

16. The semiconductor device according to claim 13, wherein
the third film includes a first layer and a second layer arranged on the first layer, and
a boundary between the first layer and the second layer is a bonding face.

17. The semiconductor device according to claim 16, wherein
the first layer includes a first semiconductor element, and
the second layer includes a second semiconductor element.

18. The semiconductor device according to claim 17, wherein
the first semiconductor element includes a memory cell array,
the second semiconductor element includes a control circuit of the memory cell array.
